(19) United States
(12) Patent Application Publication
(10) Pub. No.: US 2023/0290863 A1
(43) Pub. Date: Sep. 14, 2023

(54) SEMICONDUCTOR DEVICE AND METHODS OF FORMATION

(71) Applicant: Taiwan Semiconductor Manufacturing Company Limited, Hsinchu (TW)

(72) Inventors: Guo-Cheng LYU, New Taipei City (TW); Kun-Yu LIN, Kaohsiung City (TW); Yu-Ling KO, Hsinchu City (TW); Chih-Teng LIAO, Hsinchu City (TW)

(21) Appl. No.: 17/654,158

(22) Filed: Mar. 9, 2022

(51) Int. Cl. H01L 29/66; H01L 21/8234; H01L 21/762

(52) U.S. Cl. CPC H01L 29/66795; H01L 21/823431; H01L 21/823481; H01L 21/762

(57) ABSTRACT

Multiple-patterning techniques described herein enable forming fin structures of a semiconductor device in a manner that enables decreased fin-to-fin spacing of the fin structures while providing precise control over etching depth of the fin structures. In some implementations, an etch operation is performed to form a pattern in one or more mask layers that is used to etch a substrate to form the fin structures. The etch operation includes an advanced pulsing technique, in which a high-frequency radio frequency (RF) source and a low-frequency RF source are pulsed. Pulsing the high-frequency RF source and the low-frequency RF source in the etch operation reduces consumption of a thickness of the one or more mask layers which increases the aspect ratio of the pattern. This enables deeper etching of the substrate when forming the fin structures, which reduces the likelihood of under etching.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). As another example, in a nanostructure transistor, the gate structure wraps around a plurality of channel regions in a fin structure such that the gate structure surrounds each of the plurality of channel regions. Source/drain regions (e.g., epitaxial regions) are located on opposing sides of the gate structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example environment in which systems and/or methods described herein may be implemented.

FIG. 2 is a diagram of an example semiconductor device described herein.

FIGS. 3A-3P, 4A-4C, 5A-5D, and 6A-6C are diagrams of one or more example implementations described herein.

FIG. 7 is a diagram of example components of one or more devices of FIG. 1 described herein.

FIGS. 8-10 are flowcharts of example processes associated with forming a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As dimensions such as fin-to-fin spacing and fin width are reduced in the advancement of semiconductor manufacturing processes for fin-based semiconductor devices, various processing challenges may result. For example, the size of shallow trench isolation (STI) regions between adjacent fin structures is reduced as fin-to-fin spacing and fin width decrease. The reduced spacing of fin structures may increase the difficulty of fully etching into a substrate to a desired depth to form the fin structures, which may result in under etching of adjacent fin structures.

Under etching of adjacent fin structures may result in fin bending because of local strain, which increases the difficulty in fully removing dummy gate material from between the fin structures. In particular, dummy gate material may become “trapped” in the curvature of a curved or bent fin structure (e.g., due to fin bending). The curvature reduces the ability to directionally etch the dummy gate material. This results in residual dummy gate material that can eventually cause device leakage between replacement gate structures. In particular, residual dummy gate material may increase the likelihood of electrical bridging between gate structures that are formed over the STI regions. This electrical bridging may increase leakage in a semiconductor device that includes the gate structures (which reduces semiconductor device performance) and/or may decrease semiconductor device yield, among other examples.

Some implementations described herein provide multiple-patterning techniques (e.g., self-aligned double patterning (SADP), self-aligned quadruple patterning (SAQP)) for forming fin structures of a semiconductor device in a manner that enables decreased fin-to-fin spacing of the fin structures while providing precise control over etching depth of the fin structures. In some implementations, an etch operation is performed to form a pattern in one or more mask layers (e.g., hard mask layers, photomask layers) that is used to etch a substrate to form the fin structures. The etch operation includes an advanced pulsing technique, in which a high-frequency radio frequency (RF) source and a low-frequency RF source are pulsed. Pulsing the high-frequency RF source and the low-frequency RF source in the etch operation reduces consumption of a thickness of the one or more mask layers (e.g., reduces a magnitude of reduction in height or thickness of the one or more mask layers due to ion bombardment) which increases the aspect ratio of the pattern (e.g., the ratio of the height of the one or more mask layers to the width of the openings of the pattern in the one or more mask layers). This enables deeper etching of the substrate when forming the fin structures, which reduces the likelihood of under etching.

In this way, under etching of the fin structures (e.g., in areas between the fin structures where STI regions are to be formed) is reduced, which promotes reduced line edge roughness (LER) for the fin structures and reduces a likelihood of residual dummy gate material remaining between the fin structures. This in turn reduces a likelihood of electrical bridging between gate structures that are formed over the STI regions. The reduced likelihood of electrical bridging may decrease leakage in a semiconductor device and increase isolation in the semiconductor device, which may increase semiconductor device yield and semiconductor device performance, among other examples. Moreover, the techniques described herein enable an increased process window for etching fin structures, which enables the spacing between fin structures to be reduced while achieving desired etch depth for the fin structures. This enables increased transistor density (e.g., fin field effect transistor (finFET) density, increased nanostructure transistor density) and/or decreased semiconductor operating power, among other examples.

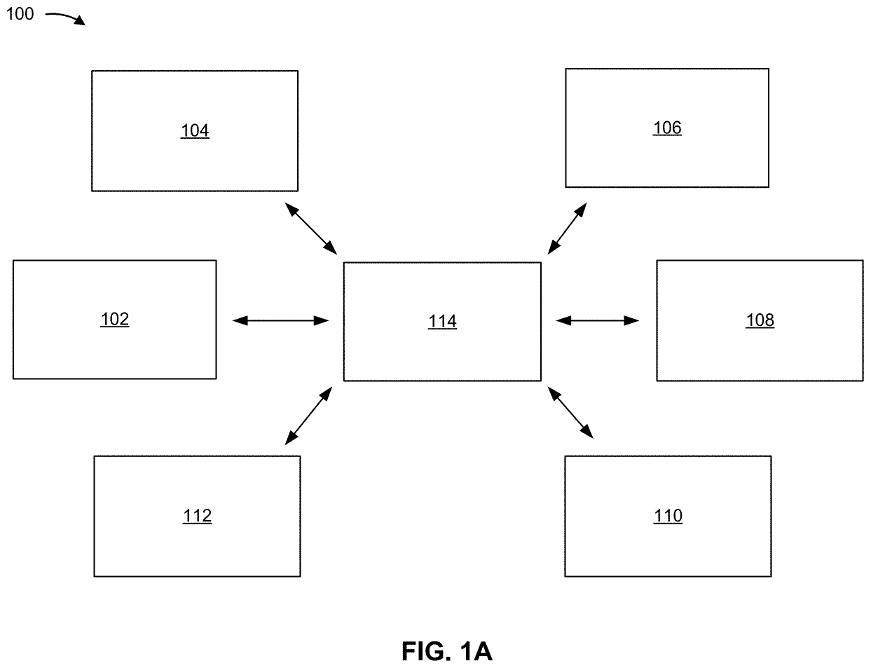

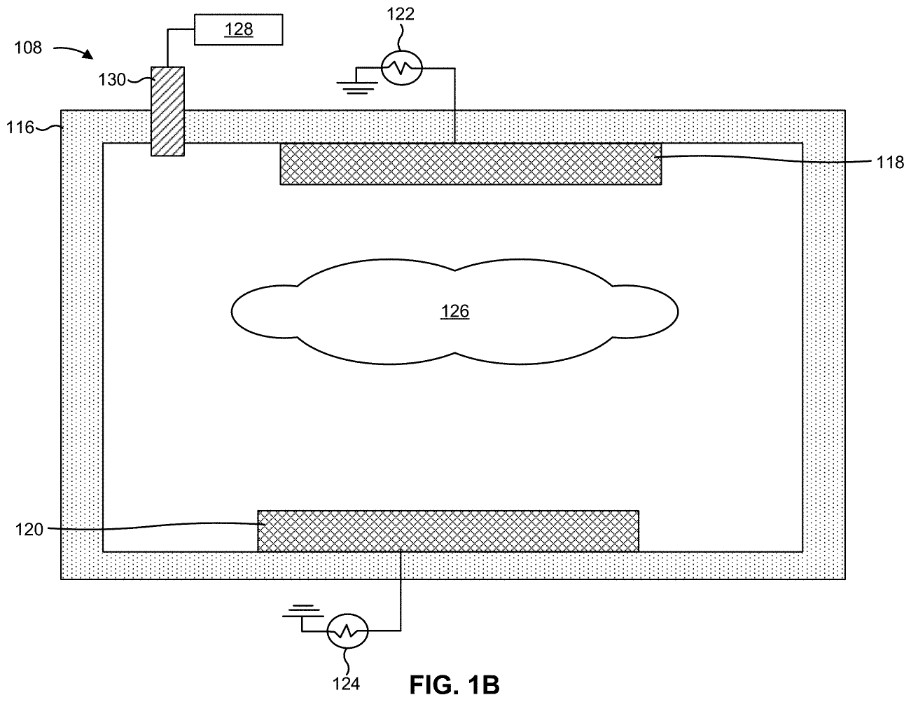

FIGS. 1A and 1B are diagrams of an example environment 100 in which systems and/or methods described herein may be implemented. As shown in FIG. 1A, environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the semiconductor processing environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

FIG. 1B illustrates an example of an etch tool 108. The etch tool 108 may include a plasma-based etch tool, which is a type of dry etch tool that uses a plasma and ions to dry etch (e.g., sputter etch) a substrate. For example, the etch tool 108 may include a capacitance-coupled plasma (CCP) etch tool, an induction-coupled plasma (ICP) etch tool, or another type of plasma-based etch tool. However, other types of etch tools 108 may be included in the environment 100. As shown in FIG. 1B, the etch tool 108 may include a processing chamber 116 and a plurality of electrodes positioned in the chamber including a top electrode 118 and a bottom electrode 120. The top electrode 118 may be electrically connected to a high-frequency RF source 122. The bottom electrode 120 may be electrically connected to a low-frequency RF source 124.

The high-frequency RF source 122 may be configured to control and/or adjust the generation of a plasma 126 in the processing chamber 116, such as controlling the concentration of ions in the plasma 126 and/or controlling the density of the plasma 126 generated in the processing chamber 116, among other examples. The low-frequency RF source 124 may be configured to control and/or adjust ion bombardment of ions in the plasma 126 onto a substrate positioned above the lower electrode 120 (e.g., positioned on a chuck in the processing chamber 116). For example, the low-frequency RF source 124 may control the directionality of ion bombardment, may control the velocity of ion bombardment, and/or may control ion current, among other examples. The plasma 126 may include an argon (AR)-based plasma or another type of inert gas plasma.

The high-frequency RF source 122 may operate at a higher frequency relative to the low-frequency RF source 124. In some implementations, the high-frequency RF source 122 operates (e.g., generates RF power) in a frequency range of approximately 27 megahertz (MHz) to approximately 60 MHz. However, other values for the range are within the scope of the present disclosure. In some implementations, the low-frequency RF source operates (e.g., generates RF power) in a frequency range of approximately 2 MHz to approximately 16 MHz. However, other values for the range are within the scope of the present disclosure.

In some implementations, the high-frequency RF source 122 and the low-frequency RF source 124 both generate the same magnitude of RF power. In some implementations, the high-frequency RF source 122 and the low-frequency RF source 124 generate different magnitudes of RF power. In some implementations, the high-frequency RF source 122 generates RF power in a range of approximately 30 watts (W) to approximately 500 W to achieve a particular density for the plasma 126 and to achieve particular critical dimensions and/or structural profiles for semiconductor devices processed by the etch tool 108. However, other values for the range are within the scope of the present disclosure. In some implementations, the low-frequency RF source 124 generates RF power in a range of approximately 30 W to approximately 500 W to achieve a particular ion bombardment strength for the plasma 126 while reducing and/or minimizing mask layer consumption (e.g., thickness or height reduction) for mask layers that are used in patterning semiconductor devices that are processed by the etch tool 108. However, other values for the range are within the scope of the present disclosure.

As further shown in FIG. 1B, the etch tool 108 includes a gas source 128 that is configured to provide one or more types of process gasses into the processing chamber 116 through a gas inlet 130. The process gasses may include radicals (e.g., etching radicals or etchants), inert gasses (e.g., for plasma generation), and/or another type of gasses. Examples include oxygen (O₂), carbon dioxide (CO₂), argon (Ar), chlorine (Cl₂), and/or a hydrofluorocarbon (HFC) such as fluoromethane (CH₃F), among other examples.

As described herein, the high-frequency RF source 122 and/or the low-frequency RF source 124 may be pulsed during an etch operation associated with a semiconductor device to enable precise control over pattern formation in one or more mask layers formed on the semiconductor device. As an example, the high-frequency RF source 122 may be pulsed to enable precise control over formation of the plasma 126 in the processing chamber 116, whereas the low-frequency RF source 124 may be pulsed to enable precise control over ion bombardment of ions in the plasma 126 and/or radical bombardment onto the one or more mask layers. Pulsing the high-frequency RF source 122 and/or the low-frequency RF source 124 may reduce consumption of the one or more mask layers (e.g., may reduce a magnitude of reduction in height of the one or more mask layers due that occurs due to ion bombardment), which enables a pattern to be formed in the one or more mask layers to a greater aspect ratio (e.g., the height of the pattern is increased relative to the width of the openings in the pattern). The increased aspect ratio may promote reduced LER for structures that are formed on the semiconductor device and may promote increased etch depth for the structures, which reduces the likelihood of under etch defect formation in the semiconductor device.

Pulsing may refer to a technique by which an RF source (e.g., the high-frequency RF source 122, the low-frequency RF source 124) is operated according to an on-and-off duration, in which the RF source is sequentially transitioned between an on duration (in which the RF source is on and performing a “duty” of generating RF power) and an off duration (in which the RF source is off and not generating RF power). The ratio between the time duration of the on duration and the time duration of the off duration in an on-and-off duration is referred to as a duty cycle. As an example, if the time duration of an on duration is 80% of an on-and-off duration and the time duration of an off duration is 20% of the on-and-off duration, the duty cycle of the RF source is 80%.

The number and arrangement of devices shown in FIGS. 1A and 1B are provided as one or more examples. In practice, there may be additional devices, fewer devices, different devices, or differently arranged devices than those shown in FIGS. 1A and 1B. Furthermore, two or more devices shown in FIGS. 1A and 1B may be implemented within a single device, or a single device shown in FIGS. 1A and 1B may be implemented as multiple, distributed devices. Additionally, or alternatively, a set of devices (e.g., one or more devices) of environment 100 may perform one or more functions described as being performed by another set of devices of environment 100.

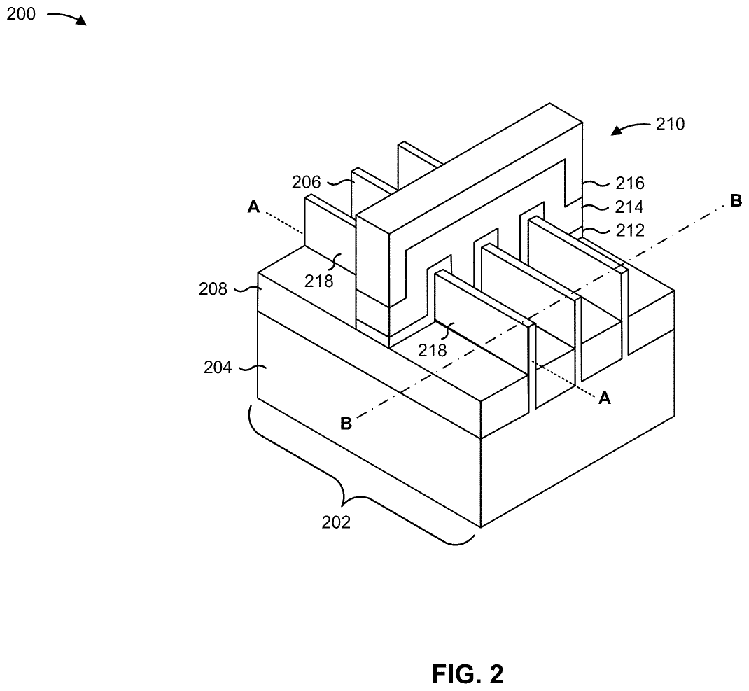

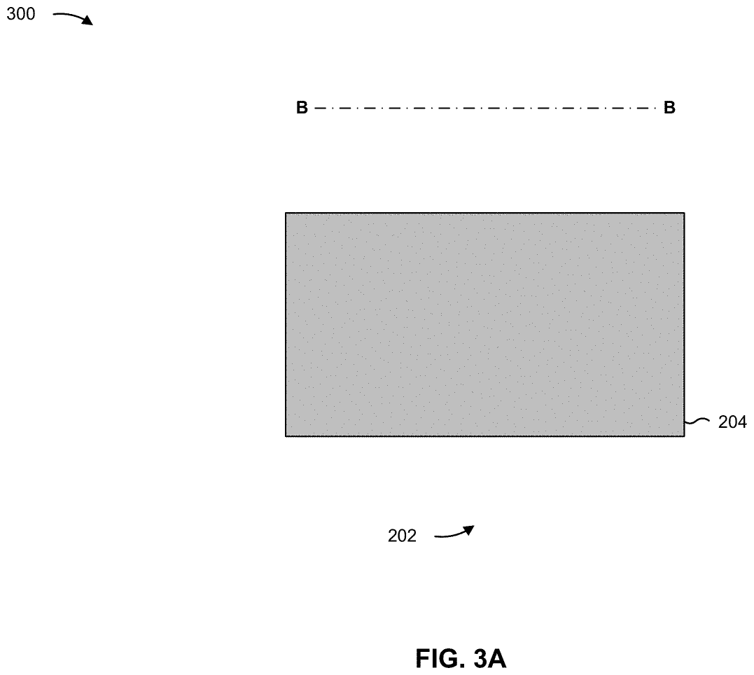

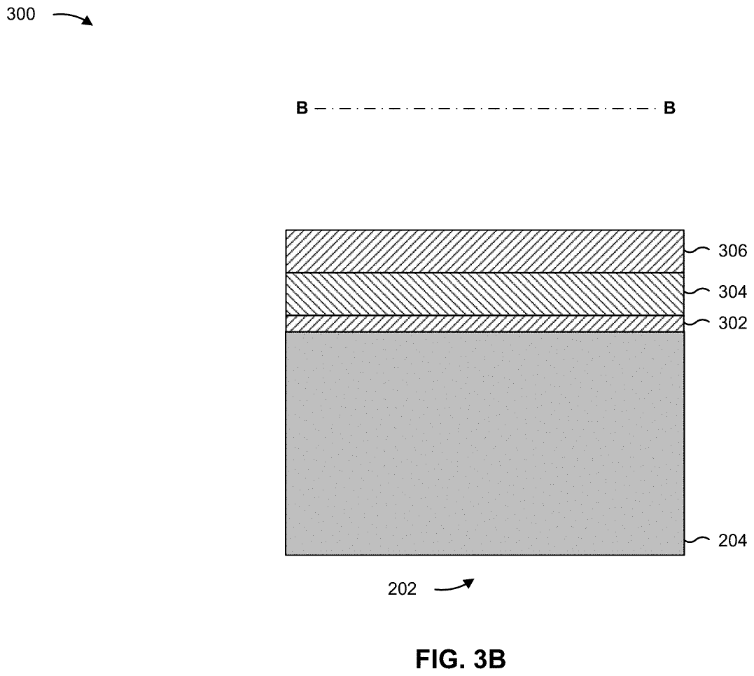

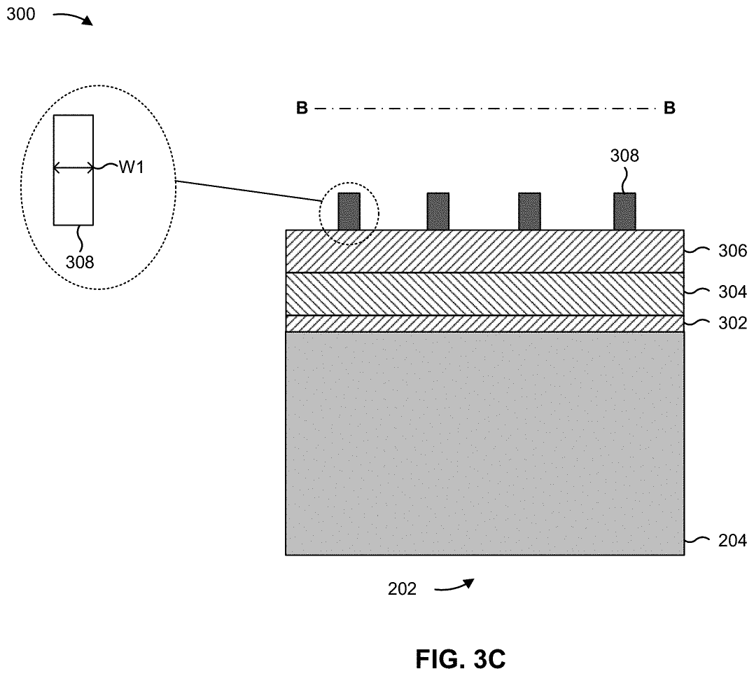

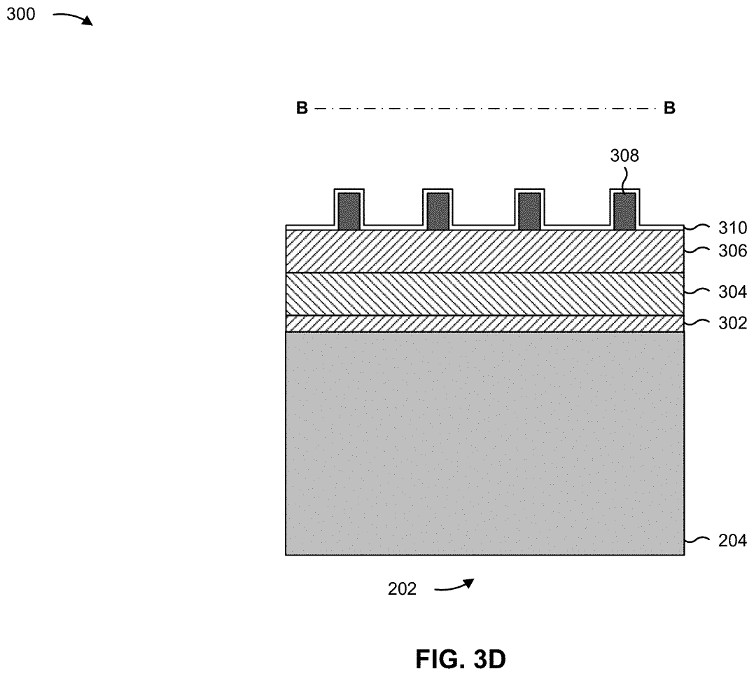

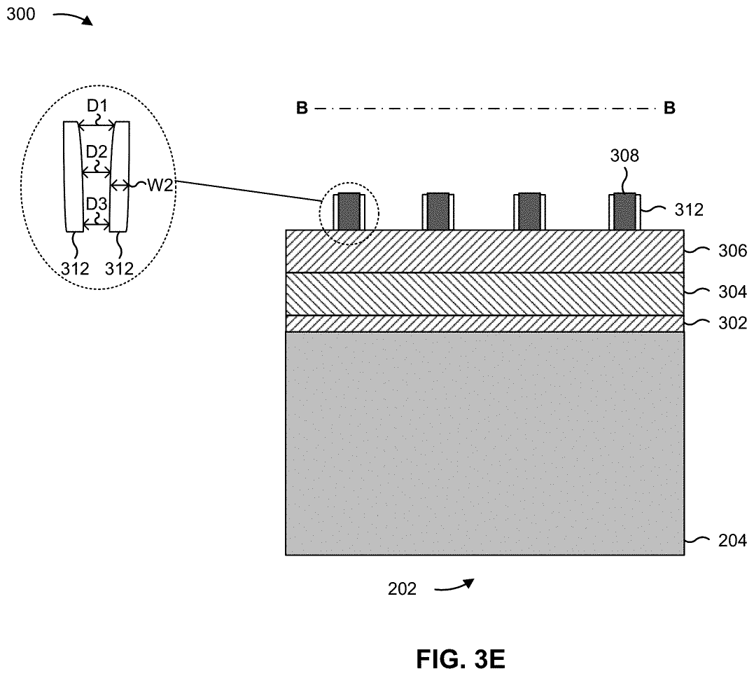

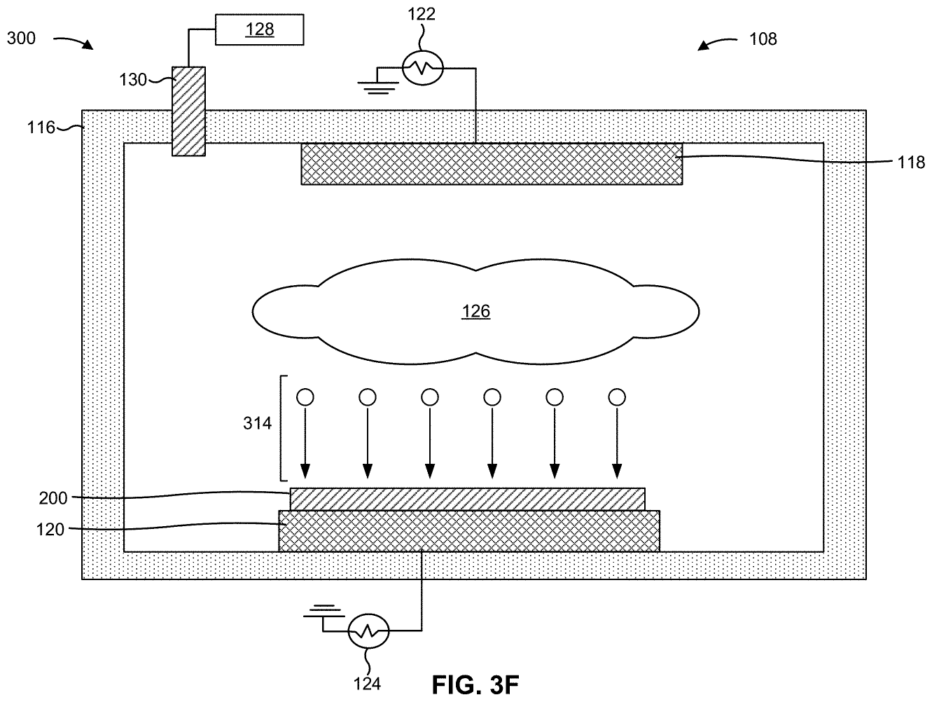

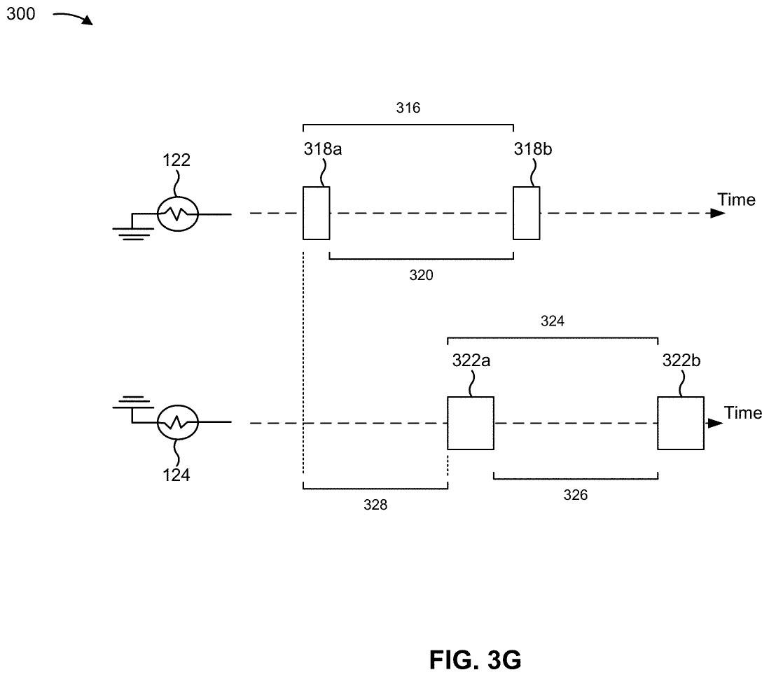

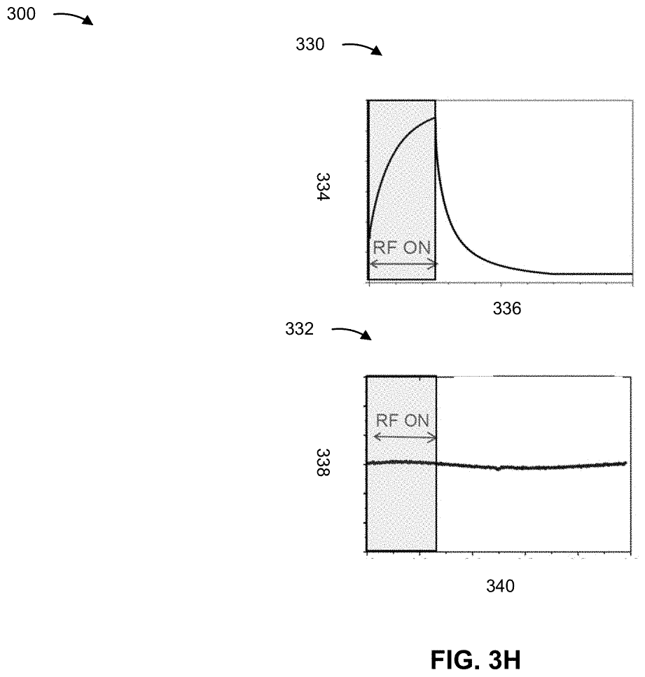

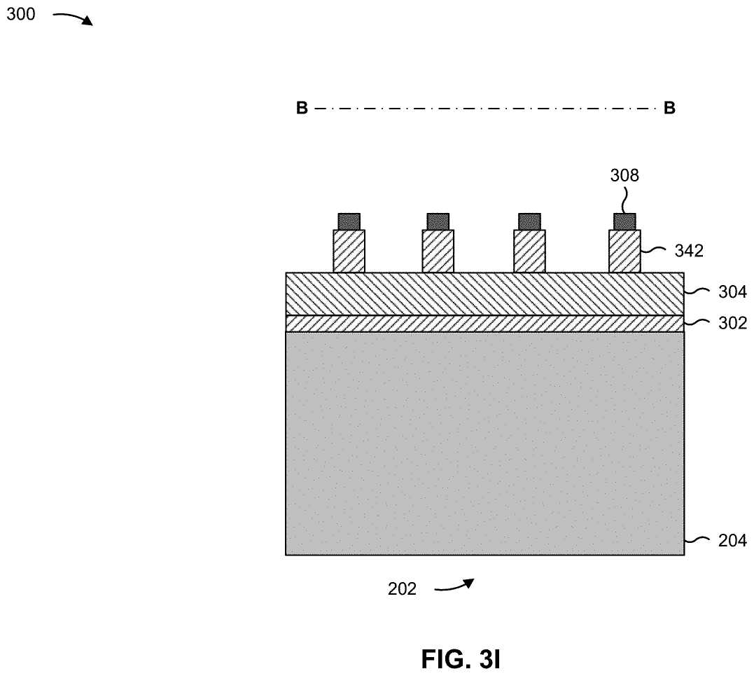

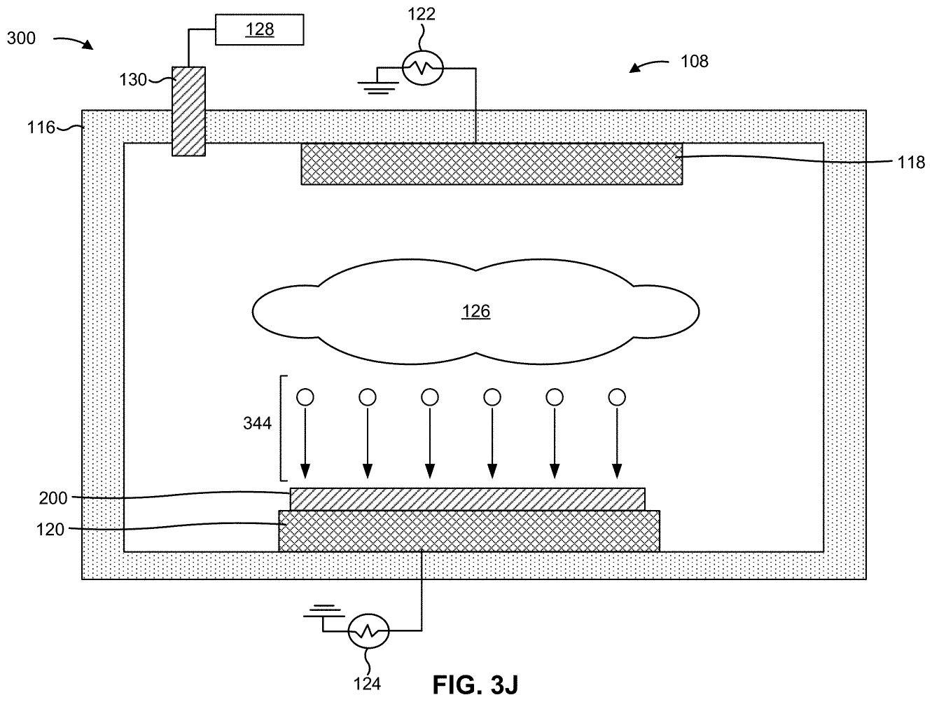

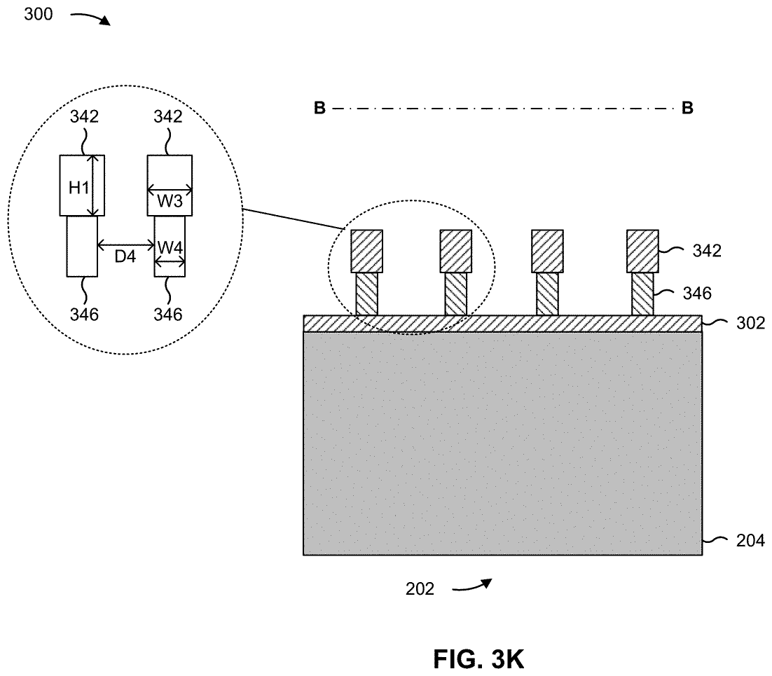

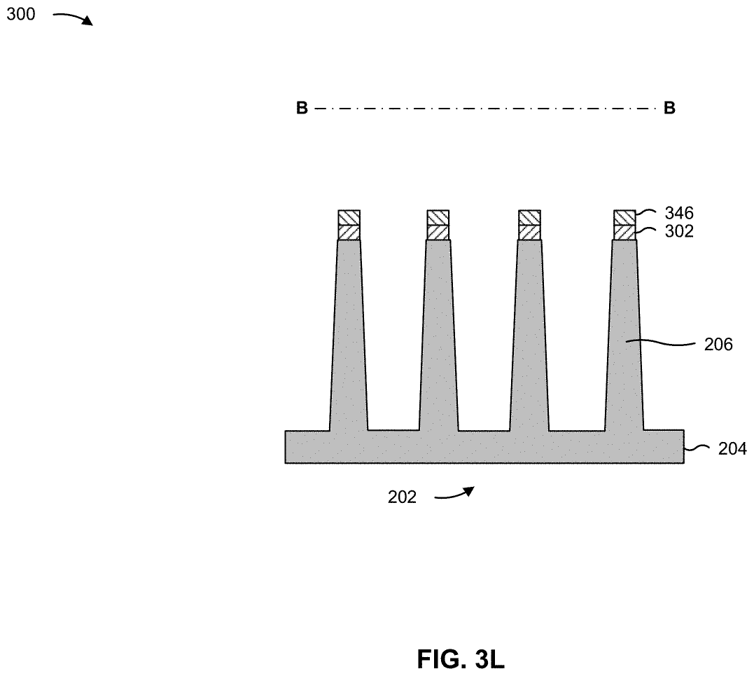

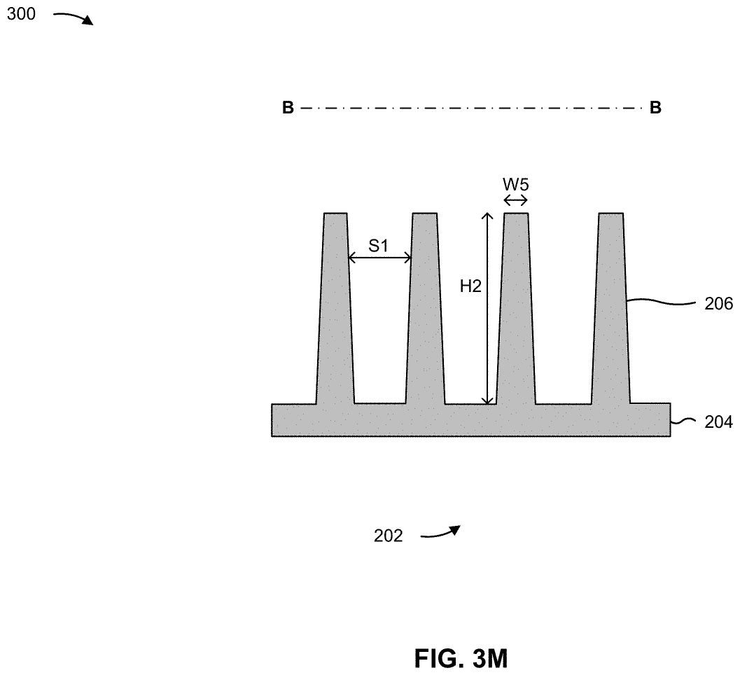

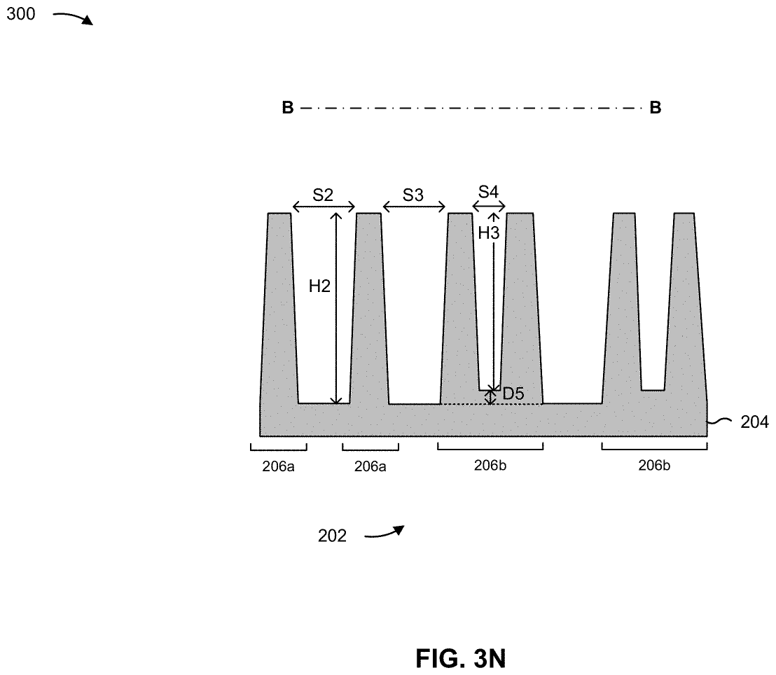

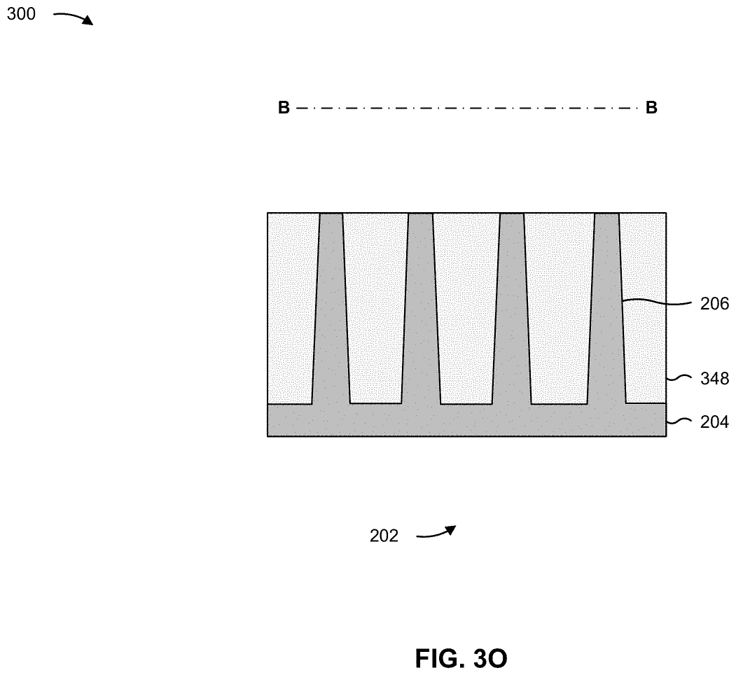

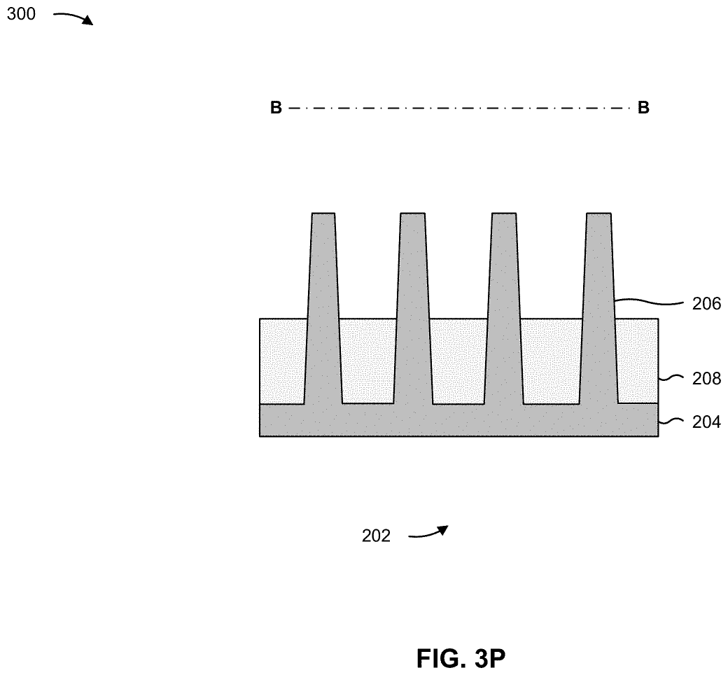

FIG. 2 is a diagram of example regions of a semiconductor device 200 described herein. In particular, FIG. 2 illustrates an example device region 202 of the semiconductor device 200 in which one or more transistors or other devices are included. The transistors may include fin-based transistors, such as fin field effect transistors (finFETs), nanostructure transistors, and/or other types of transistors. In some implementations, the device region 202 includes a p-type metal oxide semiconductor (PMOS) region, an n-type metal oxide semiconductor (NMOS) region, a complementary metal oxide semiconductor (CMOS) region, and/or another type of device region. FIGS. 3A-6C are schematic cross-sectional views of various portions of the device region 202 of the semiconductor device 200 illustrated in FIG. 2, and correspond to various processing stages of forming fin-based transistors in the device region 202 of the semiconductor device 200.

The semiconductor device 200 includes a substrate 204. The substrate 204 includes a silicon (Si) substrate, a substrate formed of a material including silicon, a III-V compound semiconductor material substrate such as gallium arsenide (GaAs), a silicon on insulator (SOT) substrate, a germanium substrate (Ge), a silicon germanium (SiGe) substrate, or another type of semiconductor substrate. The substrate 204 may include a round/circular substrate having an approximately 200 mm diameter, an approximately 300 mm diameter, or another diameter, such as 450 mm, among other examples. The substrate 204 may alternatively be any polygonal, square, rectangular, curved, or otherwise non-circular workpiece, such as a polygonal substrate.

Fin structures 206 are included above (and/or extend above) the substrate 204 for the device region 202. A fin structure 206 may provide an active region where one or more devices (e.g., fin-based transistors) are formed. In some implementations, the fin structures 206 include silicon (Si) materials or another elementary semiconductor material such as germanium (Ge). In some implementations, the fin structures 206 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof. In some implementations, the fin structures 206 are doped using n-type and/or p-type dopants.

The fin structures 206 are fabricated by suitable semiconductor process techniques, such as masking, photolithography, and/or etch processes, among other examples. As an example, the fin structures 206 may be formed by etching a portion of the substrate 204 away to form recesses in the substrate 204. The recesses may then be filled with isolating material that is recessed or etched back to form shallow trench isolation (STI) regions 208 above the substrate 204 and between the fin structures 206. Other fabrication techniques for the STI regions 208 and/or for the fin structures 206 may be used. The STI regions 208 may electrically isolate adjacent active areas in the fin structures 206. The STI regions 208 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. The STI regions 208 may include a multi-layer structure, for example, having one or more liner layers.

A dummy gate structure 210 (or a plurality of dummy gate structures 210) is included in the device region 202 over the fin structures 206 (e.g., approximately perpendicular to the fin structures 206). The dummy gate structure 210 engages the fin structures 206 on three or more sides of the fin structures 206. In the example depicted in FIG. 2, the dummy gate structure 210 includes a gate dielectric layer 212, a gate electrode layer 214, and a hard mask layer 216. In some implementations, the dummy gate structure 210 further includes a capping layer, one or more spacer layers, and/or another suitable layer. The various layers of the dummy gate structure 210 may be formed by suitable deposition techniques and patterned by suitable photolithography and etching techniques.

The term, “dummy”, as described here, refers to a sacrificial structure which will be removed in a later stage and will be replaced with another structure, such as a high dielectric constant (high-k) dielectric and metal gate structure in a replacement gate process. The replacement gate process refers to manufacturing a gate structure at a later stage of the overall gate manufacturing process. Accordingly, the configuration of the semiconductor device 200 illustrated in FIG. 2 may include an intermediate configuration, and additional semiconductor processing operations may be performed for the semiconductor device 200 to further process the semiconductor device 200.

The gate dielectric layer 212 may include a dielectric oxide layer. The dielectric oxide layer may be formed by chemical oxidation, thermal oxidation, ALD, CVD, and/or other suitable methods. The gate electrode layer 214 may include a poly-silicon material or another suitable material. The gate electrode layer 214 may be formed by suitable deposition processes such as LPCVD or PECVD, among other examples. The hard mask layer 216 may include any material suitable to pattern the gate electrode layer 214 with particular features/dimensions on the substrate 204.

In some implementations, the various layers of the dummy gate structure 210 are first deposited as blanket layers. Then, the blanket layers are patterned through a process including photolithography and etching processes, removing portions of the blanket layers and keeping the remaining portions over the STI regions 208 and the fin structures 206 to form the dummy gate structure 210.

Source/drain areas 218 are disposed in opposing regions of the fin structures 206 with respect to the dummy gate structure 210. The source/drain areas 218 include areas in the device region 202 in which source/drain regions are to be formed. The source/drain regions in the device region 202 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the device region 202 may include PMOS transistors that include p-type source/drain regions, NMOS transistors that include n-type source/drain regions, and/or other types of transistors.

Some source/drain regions may be shared between various transistors in the device region 202. In some implementations, various ones of the source/drain regions may be connected or coupled together such that fin-based transistors in the device region 202 are implemented as two functional transistors. For example, if neighboring (e.g., as opposed to opposing) source/drain regions are electrically connected, such as through coalescing the regions by epitaxial growth (e.g., neighboring source/drain regions, as opposed to on opposing sides of the dummy gate structure 210, being coalesced), two functional transistors may be implemented. Other configurations in other examples may implement other numbers of functional transistors.

FIG. 2 further illustrates reference cross-sections that are used in later figures, including FIGS. 3A-6C. Cross-section A-A is in a plane along a channel in a fin structure 206 between opposing source/drain areas 218. Cross-section B-B is in a plane perpendicular to cross-section A-A, and is across a source/drain area 218 in fin structure 206. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

FIGS. 3A-3P are diagrams of an example implementation 300 described herein. The example implementation 300 includes an example of forming fin structures 206 for transistors in the device region 202 of the semiconductor device 200. FIGS. 3A-3E, 3I, and 3K-3P are illustrated from the perspective of the cross-sectional plane B-B in FIG. 2 for the device region 202. Turning to FIG. 3A, the example implementation 300 includes semiconductor processing operations relating to the substrate 204 in and/or on which transistors are formed in the device region 202.

As shown in FIG. 3B, a plurality of layers are formed over and/or on the substrate 204. In some implementations, the deposition tool 102 deposits the plurality of layers over and/or on the substrate 204 using a CVD technique, an ALD technique, a PVD technique, a thermal oxidation technique, an anodic nitridation technique, and/or another deposition technique. In some implementations, another semiconductor processing tool forms the plurality of layers.

The plurality of layers may include a pad oxide layer 302, a first hard mask layer 304, and a second hard mask layer 306, among other examples. The pad oxide layer 302 is formed over and/or on the substrate 204. The first hard mask layer 304 is formed over and/or on the pad oxide layer 302. The second hard mask layer 306 is formed over and/or on the first hard mask layer 304.

The pad oxide layer 302 includes a silicon oxide (SiOₓ) and/or another oxide material. The pad oxide layer 302 may function as an adhesion layer between the substrate 204 and the first hard mask layer 304. Moreover, the pad oxide layer 302 may function as an etch stop layer for etching the first hard mask layer 304. In some implementations, the pad oxide layer 302 is formed to a thickness in a range of approximately 1 nanometer (nm) to approximately 5 nanometers (nm). However, other values for the range are within the scope of the present disclosure.

The first hard mask layer 304 and the second hard mask layer 306 may be used to pattern the substrate 204 in the formation of the fin structures 206 of the semiconductor device 200. In some implementations, the first hard mask layer 304 is formed to a thickness in a range of approximately 10 nm to approximately 30 nm. In some implementations, the second hard mask layer 306 is formed to a thickness in a range of approximately 30 nm to approximately 70 nm. These ranges enable patterns to be formed in the first hard mask layer 304 and in the second hard mask layer 306 to achieve an aspect ratio for the patterns (e.g., a ratio between a height of the patterns to the width of the patterns) that enables sufficiently deep etching of the substrate 204 to form the fin structures 206 while reducing and/or minimizing under etching of the fin structures 206. However, other values for the ranges are within the scope of the present disclosure.

The first hard mask layer 304 may include a nitride material such as a silicon nitride (SiₓN_{y}) among other examples. The second hard mask layer 306 may include an oxide material such as a silicon oxide (SiOₓ) among other examples. The use of different materials for the first hard mask layer 304 and the second hard mask layer 306 enables separate patterns to be formed in the first hard mask layer 304 and the second hard mask layer 306 using separate etch operations. This multiple patterning technique enables a combined pattern (e.g., including a first pattern formed in the second hard mask layer 306 and a second pattern formed in the first hard mask layer 304) to a greater aspect ratio (e.g., a ratio between a height of the pattern to the width of the pattern) relative to using a single etch operation. The greater aspect ratio increases vertical etching into the substrate 204 and decreases lateral etching into the substrate 204, which enables the formation of fin structures 206 with reduced fin-to-fin spacing.

As shown in FIG. 3C, mandrels 308 may be formed over and/or on the second hard mask layer 306. The deposition tool 102 may form the mandrels 308 using a CVD technique, an ALD technique, a PVD technique, and/or another deposition technique. In some implementations, the mandrels 308 are formed by forming a pattern on the second hard mask layer 306 and depositing the mandrels 308 based on the pattern. In some implementations, a layer of material is deposited on the second hard mask layer 306, and the layer of material is etched to form the mandrels 308.

The spacing between the mandrels 308 may be configured to achieve a particular pattern spacing in the second hard mask layer 306. As further shown in FIG. 3C, the mandrels 308 may be formed to a width (W1). In some implementations, the width (W1) is included in a range of approximately 21 nm to approximately 27 nm to achieve a sufficient pattern spacing for spacers that are to be formed on opposing sides of the mandrels 308. However, other values for the range are within the scope of the present disclosure. In some implementations, the mandrels 308 are tapered such that the width (W1) is greater at a top of the mandrels 308 relative to the width (W1) at a bottom of the mandrels 308. For example, a ratio of the width (W1) at the top of the mandrels 308 to the width (W1) at the bottom of the mandrels 308 may be in a range of less than 1:1 to approximately 1:0.9. However, other values for the range are within the scope of the present disclosure.

As shown in FIG. 3D, a conformal layer 310 is formed over and/or on the mandrels 308 and over and/or on the second hard mask layer 306. The deposition tool 102 may deposit the conformal layer 310 using a CVD technique, an ALD technique, a PVD technique, and/or another deposition technique. The conformal layer 310 may be formed over and/or on the tops of the mandrels 308 and over and/or on the sidewalls of the mandrels 308. The conformal layer 310 may be formed over and/or on portions of the top surface of the second hard mask layer 306 that are not covered by the mandrels 308. The conformal layer 310 may include a silicon nitride (SiₓN_{y}) or another suitable material.

As shown in FIG. 3E, the conformal layer 310 may be etched to form spacers 312 on the sidewalls of the mandrels 308. The etch tool 108 may use a wet etch technique, a dry etch technique, and/or another etch technique to etch the conformal layer 310 to form the spacers 312. The spacers 312 may be used to pattern the second hard mask layer 306. The spacers 312 may be formed to a width (W2) that is in a range of approximately 6 nm to approximately 12 nm to provide sufficient resistance to bending of the spacers 312 while enabling reduced pattern sizing for patterning the second hard mask layer 306. However, other values for the range are within the scope of the present disclosure.

As further shown in FIG. 3E, spacers 312 on opposing sidewalls of a mandrel 308 may be angled (e.g., angled away from the mandrel 308 from the bottom of the spacers 312 to the top of the spacers 312). For example, a distance (D1) between the spacers 312 at a top of the spacers 312 may be greater relative to a distance (D2) between the spacers 312 at a middle height of the spacers 312, and the distance (D2) between the spacers 312 at the middle height of the spacers 312 may be greater relative to a distance (D3) between the spacers 312 at a bottom of the spacers 312. In some implementations, the distance (D1) between the spacers 312 at the top of the spacers 312 is in a range of approximately 25 nm to approximately 31 nm. However, other values for the range are within the scope of the present disclosure. In some implementations, the distance (D2) between the spacers 312 at the middle of the spacers 312 is in a range of approximately 22 nm to approximately 28 nm. However, other values for the range are within the scope of the present disclosure. In some implementations, the distance (D3) between the spacers 312 at the bottom of the spacers 312 is in a range of approximately 19 nm to approximately 25 nm. However, other values for the range are within the scope of the present disclosure.

In some implementations, a ratio of the distance (D1) to the distance (D3) is in a range of approximately 0.89:1 to approximately 1.41:1. However, other values for the range are within the scope of the present disclosure. In some implementations, a ratio of the distance (D1) to the distance (D3) is in a range of approximately 1:1 to approximately 1.63:1. However, other values for the range are within the scope of the present disclosure. In some implementations, a ratio of the distance (D2) to the distance (D3) is in a range of approximately 0.88:1 to approximately 1.47:1. However, other values for the range are within the scope of the present disclosure. Moreover, in some implementations, the spacers 312 may be approximately straight such that the distance (D1), the distance (D2), and the distance (D3) are all approximately equal.

As shown in FIGS. 3F-3I, the second hard mask layer 306 may be etched based on sacrificial structures (including the mandrels 308 and/or the spacers 312) to form a first pattern in the second hard mask layer 306. As shown in FIG. 3F, the semiconductor device 200 may be positioned in the processing chamber 116 of the etch tool 108 (e.g., a plasma-based etch tool). The etch tool 108 may use the high-frequency RF source 122 to generate a plasma 126 in the processing chamber 116. The plasma 126 may include ions and radicals (e.g., etchants, or etchant radicals). The etch tool 108 may use the low-frequency RF source 124 to cause ions 314 in the plasma to be directed toward the semiconductor device 200 to etch the second hard mask layer 306 based on the mandrels 308 and/or the spacers 312. In some implementations, the mandrels 308 are removed and the first pattern is formed in the second hard mask layer 306 based on the spacers 312. In some implementations, the first pattern is formed in the second hard mask layer 306 based on the mandrels 308 and the spacers 312.

As shown in FIG. 3G, the etch tool 108 may perform a pulsing technique in which the high-frequency RF source 122 and/or the low-frequency RF source 124 are pulsed to control ion bombardment onto the top surface of the second hard mask layer 306. The pulsing technique may be performed to optimize ion and radical concentrations during dry etching of the second hard mask layer 306, which reduces ion bombardment onto the top surface of the second hard mask layer 306 in areas where the second hard mask layer 306 is to remain as part of the first pattern (e.g., in unetched areas of the second hard mask layer 306). The reduced ion bombardment reduces and/or minimizes the loss in thickness of the remaining (non-removed) portions of the second hard mask layer 306. This enables the first pattern to be formed in the second hard mask layer 306 to a greater aspect ratio (e.g., to a greater ratio between the height of the first pattern relative to the width of the openings in the first pattern), which increases etch depth into the substrate 204 based on the first pattern.

The pulsing technique may include pulsing the high-frequency RF source 122 and the low-frequency RF source 124 in an alternating manner. In particular, the pulsing technique may include operating the high-frequency RF source 122 for a plurality of on-and-off durations 316. Each on-and-off duration 316 may include an on duration 318 and an off duration 320. The on durations 318 and the off durations 320 may occur sequentially and in a non-overlapping manner (e.g., non-overlapping in the time domain). For example, an on duration 318a may occur followed by an off duration 320 in a first on-and-off duration 316. Another on duration 318b in a second on-and-off duration 316 may occur after the off duration 320 of the first on-and-off duration 316. In an on duration 318, the high-frequency RF source 122 is operating and generating RF power, which facilitates the generation of the plasma 126 and the ions 314. In an off duration 320, the high-frequency RF source 122 is off and/or not generating RF power.

In some implementations, the high-frequency RF source 122 is pulsed at a frequency that is in a range of approximately 50 Hz to approximately 1000 Hz to maintain sufficient processing throughput of the etch tool 108 while increasing etch selectivity to reduce and/or minimize material removal from the remaining portions of the second hard mask layer 306. However, other values for the range are within the scope of the present disclosure. To achieve a pulsing frequency in this range, the high-frequency RF source 122 may be operated at a duty cycle of approximately 10% to approximately 45%. In other words, the high-frequency RF source 122 may be operated such that the on durations 318 of the high-frequency RF source 122 occupy approximately 10% to approximately 45% of the time durations of the on-and-off durations 316 of the high-frequency RF source 122. This may result in a duration of the on durations 318 being in a range of approximately 1 millisecond (ms) to approximately 4.5 ms for a 1 second on-and-off duration 316. However, other values for the duty cycle, the on duration range, and/or the pulsing frequency of the high-frequency RF source 122 are within the scope of the present disclosure.

The pulsing technique may further include operating the low-frequency RF source 124 for a plurality of on durations 322 in respective on-and-off durations 324. Each on-and-off duration 324 may include an on duration 322 and an off duration 326. The on durations 322 and the off durations 326 may occur sequentially and in a non-overlapping manner (e.g., non-overlapping in the time domain). For example, an on duration 322a may occur followed by an off duration 326 in a first on-and-off duration 324. Another on duration 322b in a second on-and-off duration 324 may occur after the off duration 326 of the first on-and-off duration 324. In an on duration 322, the low-frequency RF source 124 is operating and generating RF power, which facilitates the flow of the ions 314 and radicals in the plasma 126 toward the semiconductor device 200. In an off duration 326, the low-frequency RF source 124 is off and/or not generating RF power.

In some implementations, the low-frequency RF source 124 is pulsed at a frequency that is in a range of approximately 50 Hz to approximately 1000 Hz to maintain sufficient processing throughput of the etch tool 108 while increasing etch selectivity to reduce and/or minimize material removal from the remaining portions of the second hard mask layer 306. However, other values for the range are within the scope of the present disclosure. To achieve a pulsing frequency in this range, the low-frequency RF source 124 may be operated at a duty cycle of approximately 10% to approximately 45%. In other words, the low-frequency RF source 124 may be operated such that the on durations 322 of the low-frequency RF source 124 occupy approximately 10% to approximately 45% of the time durations of the on-and-off durations 324 of the low-frequency RF source 124. This may result in a duration of the on durations 322 being in a range of approximately 1 ms to approximately 4.5 ms for a 1 second on-and-off duration 324. However, other values for the duty cycle, the on duration range, and/or the pulsing frequency of the low-frequency RF source 124 are within the scope of the present disclosure.

In some implementations, the time durations of the on durations 318 and the on durations 322 may be the same or similar time durations. In some implementations, the time durations of the on durations 318 and the on durations 322 may be different time durations. For example, the duty cycle of the low-frequency RF source 124 may be greater relative to the duty cycle of the high-frequency RF source 122 (e.g., the time durations of the on durations 322 may be greater relative to the time durations of the on durations 318). As another example, the duty cycle of the low-frequency RF source 124 may be lesser relative to the duty cycle of the high-frequency RF source 122 (e.g., the time durations of the on durations 322 may be lesser relative to the time durations of the on durations 318). The time duration of the on durations 318 may be increased to increase ion generation and plasma generation or may be decreased to decrease ion generation and plasm generation. As another example, the on durations 322 may be increased to increase ion current and/or ion velocity toward the semiconductor device 200 or may be decreased to decrease ion current and/or ion velocity toward the semiconductor device 200.

As further shown in FIG. 3G, the etch tool 108 may pulse the high-frequency RF source 122 and the low-frequency RF source 124 such that the on durations 318 and the on durations 322 are non-overlapping (e.g., such that the on durations 318 do not overlap with the on durations 322 and such that the on durations 322 do not overlap with the on durations 318). In this way, the on durations 318 occur during the off durations 326, and the on durations 322 occur during the off durations 320. This may be achieved through the use of an offset time duration 328 for the low-frequency RF source 124. Alternatively, the offset time duration 328 may be applied to the high-frequency RF source 122, or respective offset time durations 328 may be applied to both the high-frequency RF source 122 and the low-frequency RF source 124 such that the on durations 318 and the on durations 322 are offset and/or non-overlapping in the time domain.

The low-frequency RF source 124 may be pulsed based on the offset time duration 328 such that the starting times of the on durations 322 occur after the starting times of the on durations 318. For example, the starting time of the on duration 322a may occur after an offset time duration 328 from the starting time of the on duration 318a, the starting time of the on duration 322b may occur after an offset time duration 328 from the starting time of the on duration 318b, and so on. Thus, the offset time duration 328 results in on-and-off durations 316 and on-and-off durations 324 being staggered or offset in the time domain. In some implementations, the high-frequency RF source 122 and the low-frequency RF source 124 are pulsed such that the starting times of the on-and-off durations 324 occur after the starting times of the on-and-off durations 316, as shown in the example in FIG. 3G. Alternatively, the high-frequency RF source 122 and the low-frequency RF source 124 are pulsed such that the starting times of the on-and-off durations 316 occur after the starting times of the on-and-off durations 324.

In some implementations, the time duration of the offset time duration 328 includes approximately 30% to 80% of an on-and-off duration 316 for the high-frequency RF source 122 to minimize the likelihood of overlap between the on durations 318 and the on durations 322, and to provide sufficient etch selectivity to reduce and/or minimize material removal from the remaining portions of the second hard mask layer 306. However, other values for the range are within the scope of the present disclosure. In some implementations, the time duration of the offset time duration 328 includes approximately 30% to 80% of an on-and-off duration 324 for the low-frequency RF source 124 to minimize the likelihood of overlap between the on durations 318 and the on durations 322, and to provide sufficient etch selectivity to reduce and/or minimize material removal from the remaining portions of the second hard mask layer 306. However, other values for the range are within the scope of the present disclosure.

FIG. 3H illustrates example parameters in an on-and-off duration 316 for the high-frequency RF source 122 and/or in an on-and-off duration 324 for the low-frequency RF source 124. The plot 330 in FIG. 3H illustrates ion kinetics for the ions 314 in the plasma 126. The plot 332 in FIG. 3H illustrates radical kinetics for the radicals in the plasma 126.

The plot 330 illustrates ion current 334 (e.g., in milliamp (mA) centimeters (mAcm⁻²)) as a function of time 336 in an on-and-off cycle. As shown in the plot 330, the ion current increases (at a decreasing rate) during an on duration (indicated as RF ON) in the on-and-off cycle and decreases (at a decreasing rate) during an off duration in the on-and-off cycle. The plot 332 illustrates radical density (e.g., in cm⁻³) 338 as a function of time 340 in an on-and-off cycle. As shown in the plot 332, the radical density remains relatively constant throughout an on duration (indicated as RF ON) and throughout an off duration in the on-and-off cycle. Thus, pulsing the high-frequency RF source 122 and/or pulsing the low-frequency RF source 124 enables increased control of the ratio of the ions 314 to radicals in the plasma 126 by enabling control over the ion kinetics shown in the plot 330.

FIG. 3I illustrates the semiconductor device 200 after the pulsing technique is used to form a first pattern 342 in the second hard mask layer 306. The first pattern 342 may be used to form a second pattern in the first hard mask layer 304. Moreover, the first pattern 342 may be used to etch the substrate 204 to form the fin structures 206 of the semiconductor device 200. Here, the first pattern 342 may be used to define the width or critical dimension (CD) of the openings in the substrate 204 between the fin structures 206, and thus may define the fin-to-fin spacing between the fin structures 206.

As shown in FIG. 3J, the semiconductor device 200 may be positioned in the processing chamber 116 of the etch tool 108 (e.g., a plasma-based etch tool). The etch tool 108 may use the high-frequency RF source 122 to generate a plasma 126 in the processing chamber 116. The plasma 126 may include ions and radicals (e.g., etchants, or etchant radicals). The etch tool 108 may use the low-frequency RF source 124 to cause ions 344 in the plasma to be directed toward the semiconductor device 200 to etch the first hard mask layer 304 based on the first pattern 342 in the second hard mask layer 306 to form a second pattern in the first hard mask layer 304.

In some implementations, the etch tool 108 performs a first etch operation to form the first pattern 342 in the second hard mask layer 306, and then performs a second etch operation to form the second pattern in the first hard mask layer 304 without removal of the semiconductor device 200 from the processing chamber 116. In other words, the first etch operation and the second etch operation are performed in-situ. Alternatively, the second etch operation may be performed after an intervening ashing operation or pre-cleaning operation, or the first etch operation and the second etch operation may be performed in different etch tools 108.

In some implementations, the etch tool 108 may perform a plurality of etch operations to form the second pattern in the first hard mask layer 304. For example, the etch tool 108 may perform a first etch operation to etch a first portion of the first hard mask layer 304, and may then perform a second etch operation to etch a second portion of the first hard mask layer 304 to form the second pattern. This two-step (or multi-step) etch technique may enable precise control over the etch depth when forming the second pattern in the first hard mask layer 304.

The pulsing technique may be similar to the pulsing technique described in connection with FIGS. 3F-3I, and may use similar parameters and/or similar parameter settings or may use different parameters and/or different parameter settings. The pulsing technique may be performed to pulse the high-frequency RF source 122 and/or the low-frequency RF source 124 to control ion bombardment onto the top surface of the second hard mask layer 306. The pulsing technique may be performed to optimize ion and radical concentrations during dry etching of the first hard mask layer 304, which reduces ion bombardment onto the top surface of the second hard mask layer 306 in areas that remain as part of the first pattern 342. The reduced ion bombardment reduces and/or minimizes the loss in thickness of the remaining (non-removed) portions of the second hard mask layer 306, which reduces loss in height of the first pattern 342. This enables the first pattern 342 and the second pattern to be formed to a greater aspect ratio, which promotes increased etch depth into the substrate 204 based on the first pattern 342 and the second pattern.

In some implementations, the pulsing techniques described herein are performed to form the first pattern 342 in the second hard mask layer 306 and to form the second pattern in the first hard mask layer 304. In some implementations, the pulsing techniques described herein are performed to form the first pattern 342 in the second hard mask layer 306, and are omitted from (or not performed in) the etch operation to form the second pattern in the first hard mask layer 304. In some implementations, the pulsing techniques described herein are performed to form the second pattern in the first hard mask layer 304, and are omitted from (or not performed in) the etch operation to form the first pattern 342 in the second hard mask layer 306.

FIG. 3K illustrates the semiconductor device 200 after the pulsing technique is used to form a second pattern 346 in the first hard mask layer 304 based on the first pattern 342. The first pattern 342 and the second pattern 346 may be used to etch the substrate 204 to form the fin structures 206 in the device region 202 of the semiconductor device 200. The pad oxide layer 302 may function as an etch stop layer during the etch operation to form the second pattern 346 in the first hard mask layer 304.

As further shown in FIG. 3K, the first pattern 342 may include a height (H1) after the second pattern 346 is formed. The height (H1) may be reduced relative to the height of the first pattern 342 prior to etching of the first hard mask layer 304 to form the second pattern 346. However, the use of the pulsing techniques described herein to form the first pattern 342 and/or the second pattern 346 reduces a magnitude of a reduction in the height (H1). For example, the height (H1) after the second pattern 346 is formed may be in a range of approximately 40 nm to approximately 50 nm to provide increased etch depth when etching the substrate 204 to form the fin structures 206 and to reduce under etching of the fin structures 206. However, other values for the range are within the scope of the present disclosure.

As further shown in FIG. 3K, the first pattern 342 (e.g., features or structures of the first pattern 342) may be formed to width (W3) and the second pattern 346 (e.g., features or structures of the second pattern 346) may be formed to a width (W4). In some implementations, the width (W3) is greater relative to the width (W4). Alternatively, the width (W4) is greater relative to the width (W3), or the width (W3) and the width (W4) may be approximately equal. In some implementations, the width (W3) is in a range of approximately 12 nm to approximately 18 nm. However, other values for the range are within the scope of the present disclosure. In some implementations, the width (W4) is in a range of approximately 8 nm to approximately 13 nm. However, other values for the range are within the scope of the present disclosure. In some implementations, a ratio of the width (W3) to the width (W4) is in a range of approximately 2.25:1 to approximately 0.92:1. However, other values for the range are within the scope of the present disclosure.

As further shown in FIG. 3K, the spacing between features or structures of the first pattern 342 and/or the second pattern 346 may be formed to a distance (D4). In some implementations, the distance (D4) is included in a range of approximately 12 nm to approximately 18 nm to enable reduced fin-to-fin spacing for the fin structures 206 formed based on the first pattern 342 and the second pattern 346. However, other values for the range are within the scope of the present disclosure.

As shown in FIG. 3L, the fin structures 206 are formed in the substrate 204 in the device region 202. In particular, the etch tool 108 etches the substrate 204 based on the first pattern 342 and the second pattern 346 to form the fin structures 206 in the substrate. In some implementations, an ashing operation may be performed to remove remaining portions of the first pattern 342 and remaining portions of the second pattern 346 from the fin structures 206 after the substrate 204 is etched.

FIGS. 3M and 3N illustrate example dimensions of the fin structures 206 formed in the device region 202 of the semiconductor device 200 using the pulsing techniques described herein. FIG. 3M illustrates example dimensions for an input/output (I/O) device. FIG. 3N illustrates example dimensions for a static random access memory (SRAM) device.

As shown in FIG. 3M, an example dimension includes a spacing (S1) between fin structures 206. In some implementations, the spacing (S1) is included in a range of approximately 14 nm to approximately 16 nm. However, other values for the range are within the scope of the present disclosure. Another example dimension includes a width (W5) or critical dimension of a fin structure 206. In some implementations, the width (W5) is included in a range of approximately 7.5 nm to approximately 8.5 nm. However, other values for the range are within the scope of the present disclosure. Another example dimension includes a height (H2) of a fin structure 206. In some implementations, the height (H2) is included in a range of approximately 115 nm to approximately 125 nm. However, other values for the range are within the scope of the present disclosure.

As shown in FIG. 3N, an SRAM device may include different types of fin structures 206 (or fin structures for different types of transistor devices). For example, the SRAM device may include p-type fin structures 206a and n-type fin structures 206b. The p-type fin structures 206a may be included in p-type transistors of the SRAM device, and the n-type fin structures 206b may be included in n-type transistors of the SRAM device.

As further shown in FIG. 3N, an example dimension includes a spacing (S2) between p-type fin structures 206a. In some implementations, the spacing (S2) is included in a range of approximately 40 nm to approximately 43 nm. However, other values for the range are within the scope of the present disclosure. Another example dimension includes a spacing (S3) between a p-type fin structure 206a and an n-type fin structure 206b. In some implementations, the spacing (S3) is included in a range of approximately 40 nm to approximately 43 nm. However, other values for the range are within the scope of the present disclosure. Another example dimension includes a spacing (S4) between n-type fin structures 206b. In some implementations, the spacing (S4) is included in a range of approximately 14 nm to approximately 16 nm. However, other values for the range are within the scope of the present disclosure.

Another example dimension includes a height (H2) of a p-type fin structure 206a. In some implementations, the height (H2) is included in a range of approximately 118 nm to approximately 130 nm. However, other values for the range are within the scope of the present disclosure. Another example dimension includes a height (H3) of an n-type fin structure 206b. In some implementations, the height (H3) is included in a range of approximately 105 nm to approximately 120 nm. However, other values for the range are within the scope of the present disclosure.

The pulsing techniques described herein are particularly suitable for increasing etch depth (and reducing under etching) between n-type fin structures 206b. For example, the pulsing techniques described herein may reduce and/or minimize the difference in height between p-type fin structures 206a and n-type fin structures 206b. In some implementations, the difference (D5) in height between p-type fin structures 206a and n-type fin structures 206b is in a range of approximately 10 nm to approximately 15 nm. In some implementations, the difference (D5) in height between p-type fin structures 206a and n-type fin structures 206b is less than approximately 10 nm as a result of the pulsing techniques described herein. However, other values for the range are within the scope of the present disclosure.

The pulsing techniques described herein may increase the process window to achieve a particular LER performance (or while promoting reduced LER) for etching the fin structures 206 of the semiconductor device 200 and/or to achieve a particular under etch performance. For example, the pulsing techniques described herein may provide a 0.5 nm decrease in fin-to-fin spacing while achieving similar six-sigma performance for under etching relative to forming the fin structures 206 without the pulsing techniques described herein.

As shown in FIG. 3O, an STI layer 348 is formed in between the fin structures 206. The deposition tool 102 deposits the STI layer 348 using a CVD technique, a PVD technique, an ALD technique, a deposition technique described above in connection with FIG. 1A, and/or another deposition technique. In some implementations, the STI layer 348 is formed to a height that is greater than the height of the fin structures 206. In these implementations, the planarization tool 110 performs a planarization (or polishing) operation to planarize the STI layer 348 such that the top surface of the STI layer 348 is substantially flat and smooth, and such that the top surface of the STI layer 348 and the top surface of the fin structures 206 are approximately the same height. The planarization operation may increase uniformity in the STI regions 208 that are formed from the STI layer 348 in a subsequent etch-back operation.

As shown in FIG. 3P, the STI layer 348 is etched in an etch back operation to expose portions of the fin structures 206. The etch tool 108 etches a portion of the STI layer 348 using a plasma etch technique, a wet chemical etch technique, and/or another type of etch technique. The remaining portions of the STI layer 348 between the fin structures 206 include the STI regions 208. In some implementations, the STI layer 348 is etched such that the height of the exposed portions of the fin structures 206 (e.g., the portions of the fin structures 206 that are above the top surface of the STI regions 208) are the same height in the device region 202. In some implementations, a first portion of the STI layer 348 in the device region 202 is etched and a second portion of the STI layer 348 in the device region 202 is etched such that the height of exposed portions of a first subset of the fin structures 206 and the height of the exposed portions of a second subset of the fin structures 206 are different, which enables the fin heights to be tuned to achieve particular performance characteristics for the device region 202.

As indicated above, FIGS. 3A-3P are provided as an example. Other examples may differ from what is described with regard to FIGS. 3A-3P.

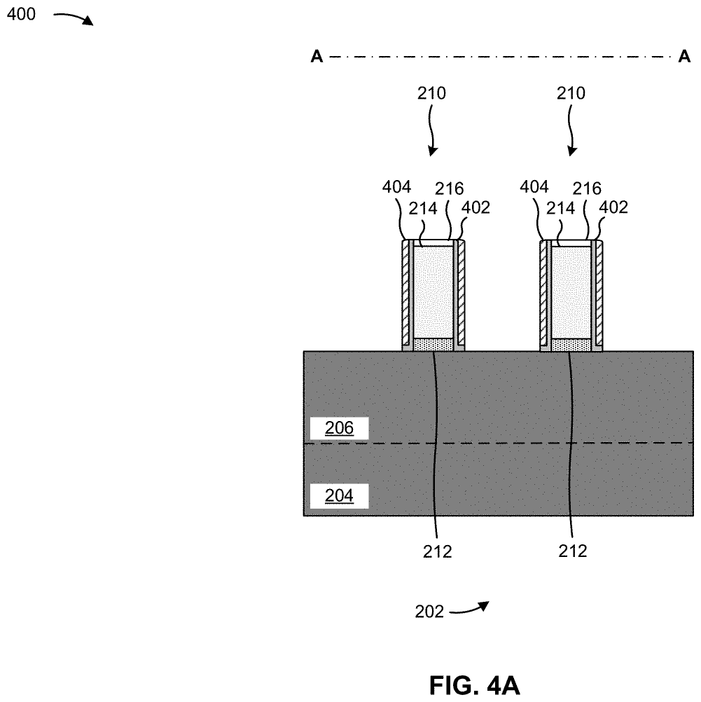

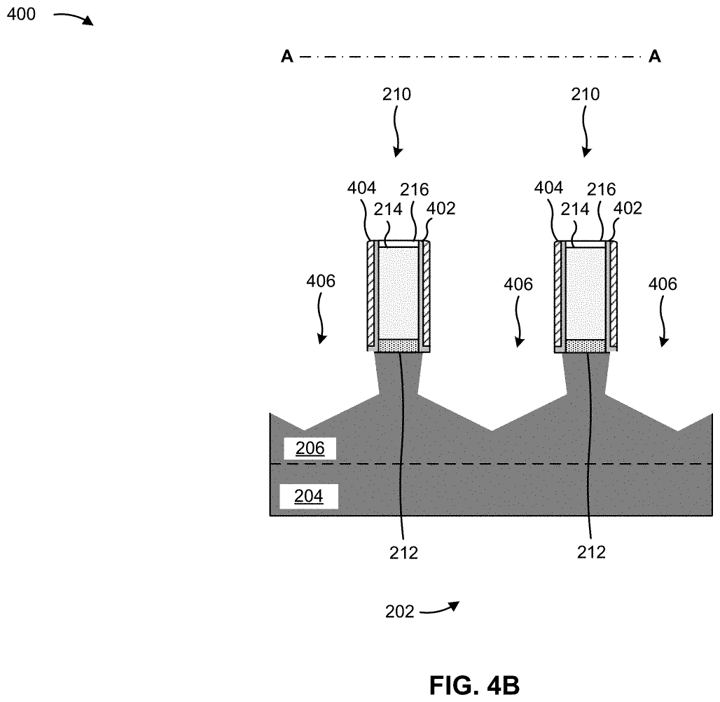

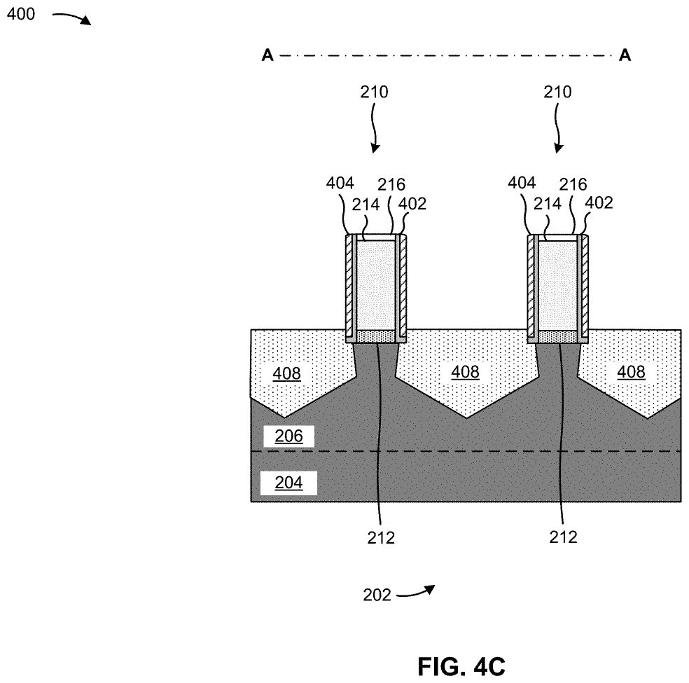

FIGS. 4A-4C are diagrams of an example implementation 400 described herein. The example implementation 400 includes an example of forming source/drain regions in the source/drain areas 218 of the device region 202 of the semiconductor device 200. FIGS. 4A-4C are illustrated from the perspective of the cross-sectional plane A-A in FIG. 2 for the device region 202. In some implementations, the operations described in connection with the example implementation 400 are performed after the fin formation process described in connection with FIGS. 3A-3P.

As shown in FIG. 4A, dummy gate structures 210 are formed in the device region 202. The dummy gate structures 210 are formed and included over the fin structures 206, and around the sides of the fin structures 206 such that the dummy gate structures 210 surround the fin structure 206 on at least three sides of the fin structure 206. The dummy gate structures 210 are formed as placeholders for the actual gate structures (e.g., replacement high-k gate structures or metal gate structures) that are to be formed for the transistors included in the device region 202. The dummy gate structures 210 may be formed as part of a replacement gate process, which enables other layers and/or structures to be formed prior to formation of the replacement gate structures.

The dummy gate structures 210 include gate dielectric layers 212, gate electrode layers 214, and hard mask layers 216. The gate dielectric layers 212 may each include dielectric oxide layers. As an example, the gate dielectric layers 212 may each be formed (e.g., by the deposition tool 102) by chemical oxidation, thermal oxidation, ALD, CVD, and/or other suitable methods. The gate electrode layers 214 may each include a poly-silicon layer or other suitable layers. For example, the gate electrode layers 214 may be formed (e.g., by the deposition tool 102) by suitable deposition processes such as LPCVD or PECVD, among other examples. The hard mask layers 216 may each include any material suitable to pattern the gate electrode layers 214 with particular dimensions and/or attributes. Examples include silicon nitride, silicon oxynitride, silicon carbon nitride, or a combination thereof, among other examples. The hard mask layers 216 may be deposited (e.g., by the deposition tool 102) by CVD, PVD, ALD, or another deposition technique.

As further shown in FIG. 4A, seal spacer layers 402 are included on the sidewalls of the dummy gate structures 210. The seal spacer layers 402 may be conformally deposited (e.g., by the deposition tool 102) and may include a silicon oxycarbide (SiOC), a nitrogen free SiOC, or another suitable material. The seal spacer layers 402 may be formed by an ALD operation in which various types of precursor gasses including silicon (Si) and carbon (C) are sequentially supplied in a plurality of alternating cycles to form the seal spacer layers 402, among other example deposition techniques.

As further shown in FIG. 4A, bulk spacer layers 404 may be formed on the seal spacer layers 402. The bulk spacer layers 404 may be formed of similar materials as the seal spacer layers 402. However, the bulk spacer layers 404 may formed without plasma surface treatment that is used for the seal spacer layers 402. Moreover, the bulk spacer layers 404 may be formed to a greater thickness relative to the thickness of the seal spacer layers 402.

In some implementations, the seal spacer layers 402 and the bulk spacer layers 404 are conformally deposited (e.g., by the deposition tool 102) on the dummy gate structures 210, and on the fin structures 206. The seal spacer layers 402 and the bulk spacer layers 404 are then patterned (e.g., by the deposition tool 102, the exposure tool 104, and the developer tool 106) and etched (e.g., by the etch tool 108) to remove the seal spacer layers 402 and the bulk spacer layers 404 from the tops of the dummy gate structures 210 and from the fin structures 206.

As shown in FIG. 4B, recesses 406 are formed in the fin structures 206 in the device region 202 between the dummy gate structures 210 in an etch operation. The etch operation may be referred to a first strained source/drain (SSD) etch operation, and the recesses 406 may be referred to as strained source/drain recesses. In some implementations, the first etch operation includes a plasma etch technique, a wet chemical etch technique, and/or another type of etch technique.

In some implementations, a plurality of etch operations are performed to form recesses 406 for different types of transistors. For example, a photoresist layer may be formed over and/or on a first subset of the fin structures 206 and over and/or on a first subset of the dummy gate structures 210 such that a second subset of the fin structures 206 between a second subset of the dummy gate structures 210 such that p-type source/drain regions and n-type source/drain regions may be formed in separate epitaxial operations.

As shown in FIG. 4C, source/drain regions 408 are formed in the recesses 406 in the device region 202 of the semiconductor device 200 over the substrate 204. The deposition tool 102 forms the source/drain regions 408 by an epitaxial operation, in which layers of the epitaxial material are deposited in the recesses 406 such that the layers of p-type source/drain regions and/or layers of n-type source/drain regions are formed by epitaxial growth in a particular crystalline orientation. The source/drain regions 408 are included between the dummy gate structures 210 and at least partially below and/or lower than the dummy gate structures 210. Moreover, the source/drain regions 408 at least partially extend above the top surface of the fin structures 206.

The material (e.g., silicon (Si), gallium (Ga), or another type of semiconductor material) that is used to form the source/drain regions 408 may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial operation. Examples of p-type dopants that may be used in the epitaxial operation include boron (B) or germanium (Ge), among other examples. The resulting material of p-type source/drain regions include silicon germanium (SiₓGe₁₋ₓ, where x can be in a range from approximately 0 to approximately 100) or another type of p-doped semiconductor material. Examples of n-type dopants that may be used in the epitaxial operation include phosphorous (P) or arsenic (As), among other examples. The resulting material of n-type source/drain regions include silicon phosphide (SiₓP_{y}) or another type of n-doped semiconductor material.

As indicated above, FIGS. 4A-4C are provided as an example. Other examples may differ from what is described with regard to FIGS. 4A-4C.

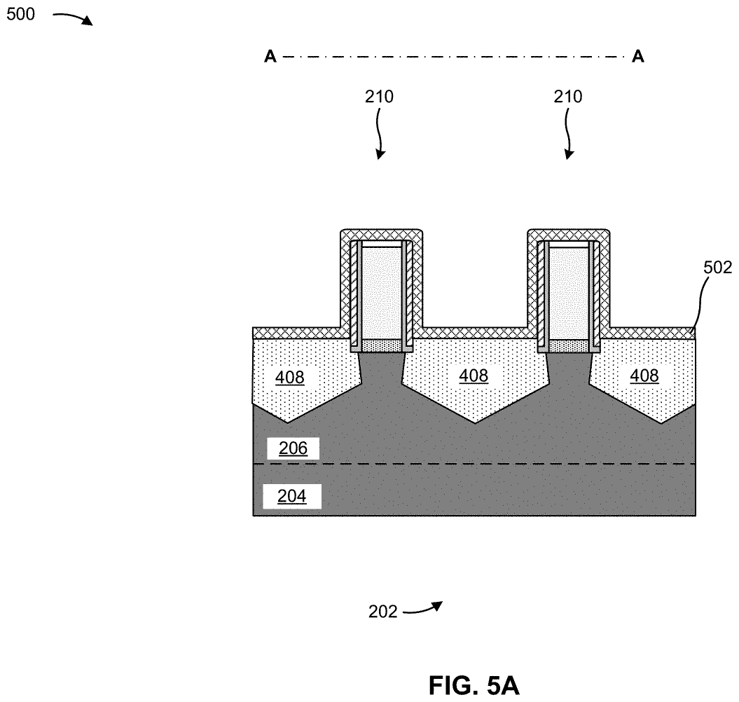

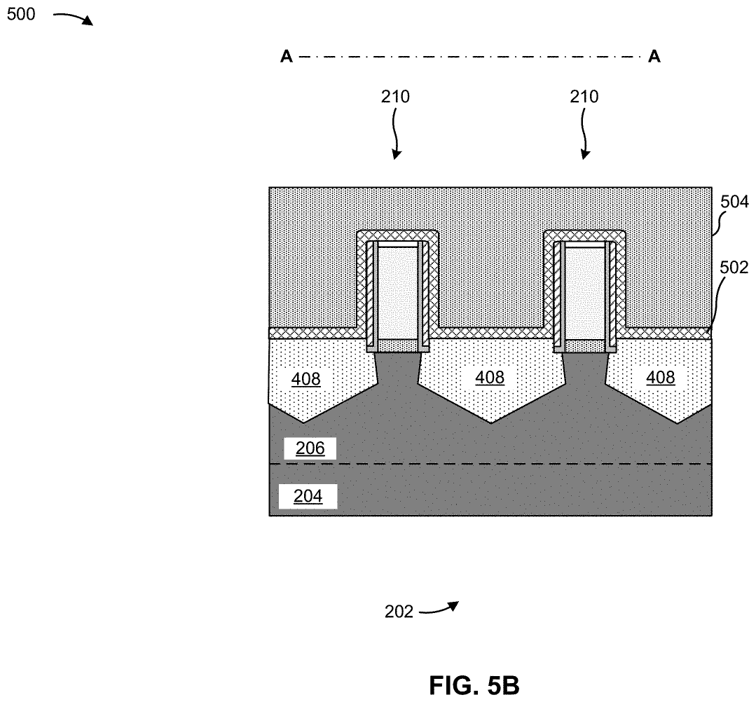

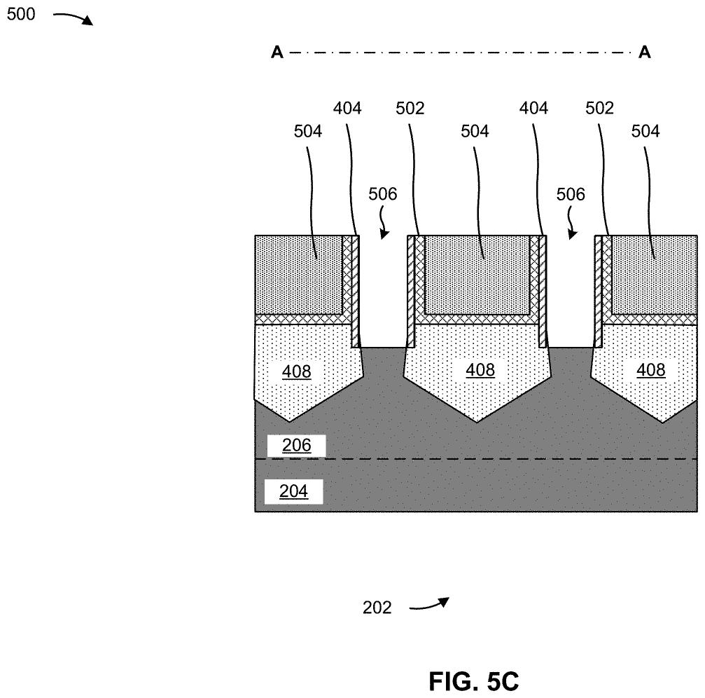

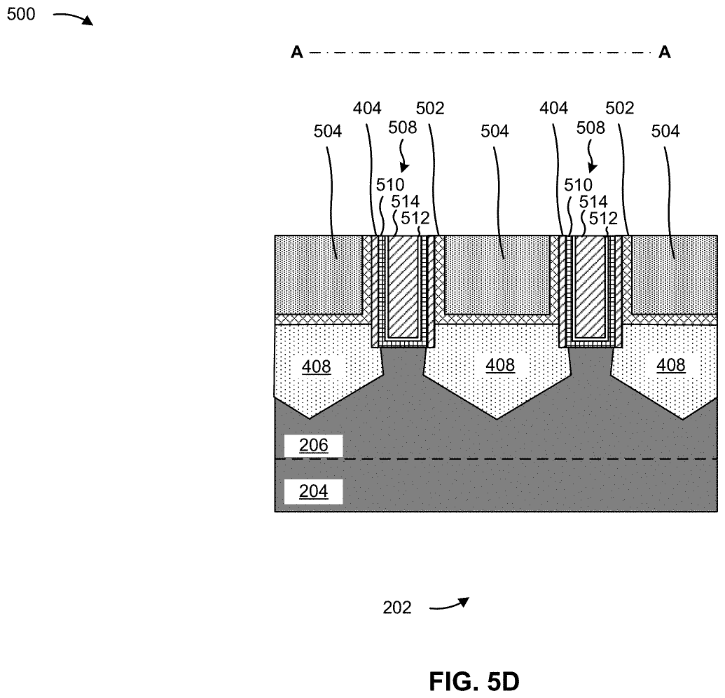

FIGS. 5A-5D are diagrams of an example implementation 500 described herein. The example implementation 500 includes an example dummy gate replacement process, in which the dummy gate structures 210 are replaced with high-k gate structures and/or metal gate structures. FIGS. 5A-5D are illustrated from the perspective of the cross-sectional plane A-A in FIG. 2 for the device region 202.

As shown in FIG. 5A, a contact etch stop layer (CESL) 502 is conformally deposited (e.g., by the deposition tool 102) over the source/drain regions 408, over the dummy gate structures 210, and on the sidewalls of the bulk spacer layers 404. The CESL 502 may provide a mechanism to stop an etch process when forming contacts or vias for the device region 202. The CESL 502 may be formed of a dielectric material having a different etch selectivity from adjacent layers or components. The CESL 502 may include or may be a nitrogen containing material, a silicon containing material, and/or a carbon containing material. Furthermore, the CESLs 502a and 502b may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 502 may be deposited using a deposition process, such as ALD, CVD, or another deposition technique.

As shown in FIG. 5B, an interlayer dielectric (ILD) layer 504 is formed (e.g., by the deposition tool 102) over and/or on the CESL 502. The ILD layer 504 fills in the areas between the dummy gate structures 210 over the source/drain regions 408. The ILD layer 504 is formed to permit a replacement gate structure process to be performed in the device region 202, in which metal gate structures are formed to replace the dummy gate structures 210. The ILD layer 504 may be referred to as an ILD zero (ILDO) layer.

In some implementations, the ILD layer 504 is formed to a height (or thickness) such that the ILD layer 504 covers the dummy gate structures 210. In these implementations, a subsequent CMP operation (e.g., performed by the planarization tool 110) is performed to planarize the ILD layer 504 such that the top surfaces of the ILD layer 504 are approximately at a same height as the top surfaces of the dummy gate structures 210. The increases the uniformity of the ILD layer 504.

As shown in FIG. 5C, the replacement gate operation is performed (e.g., by one or more of the semiconductor processing tools 102-112) to remove the dummy gate structures 210 from the device region 202. The removal of the dummy gate structures 210 leaves behind openings (or recesses) 506 between the bulk spacer layers 404 and between the source/drain regions 408. The dummy gate structures 210 may be removed in one or more etch operations includes a plasma etch technique, which may include a wet chemical etch technique, and/or another type of etch technique.

As shown in FIG. 5D, the replacement gate operation continues where deposition tool 102 and/or the plating tool 112 forms the gate structures (e.g., replacement gate structures) 508 in the openings 506 between the bulk spacer layers 404 and between the source/drain regions 408. The gate structures 508 may include metal gate structures, high-k gate structures, or other types of gate structures. The gate structures 508 may include an interfacial layer (not shown), a high-k dielectric layer 510, a work function tuning layer 512, and a metal electrode structure 514 formed therein to form a gate structure 508. In some implementations, the gate structures 508 may include other compositions of materials and/or layers.

As indicated above, FIGS. 5A-5D are provided as an example. Other examples may differ from what is described with regard to FIGS. 5A-5D.

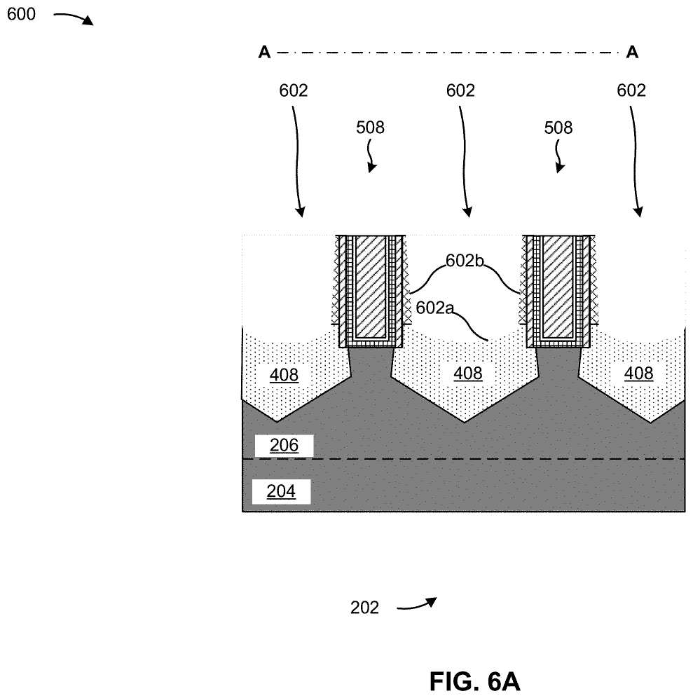

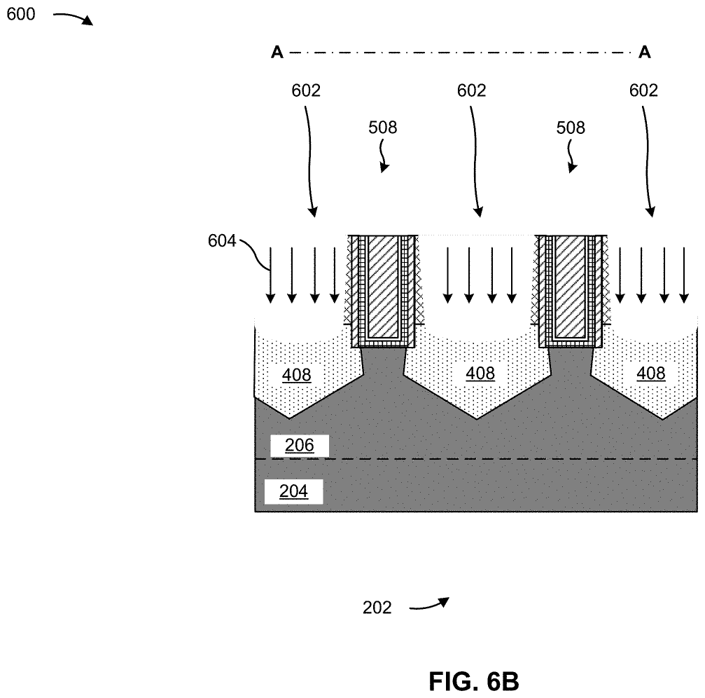

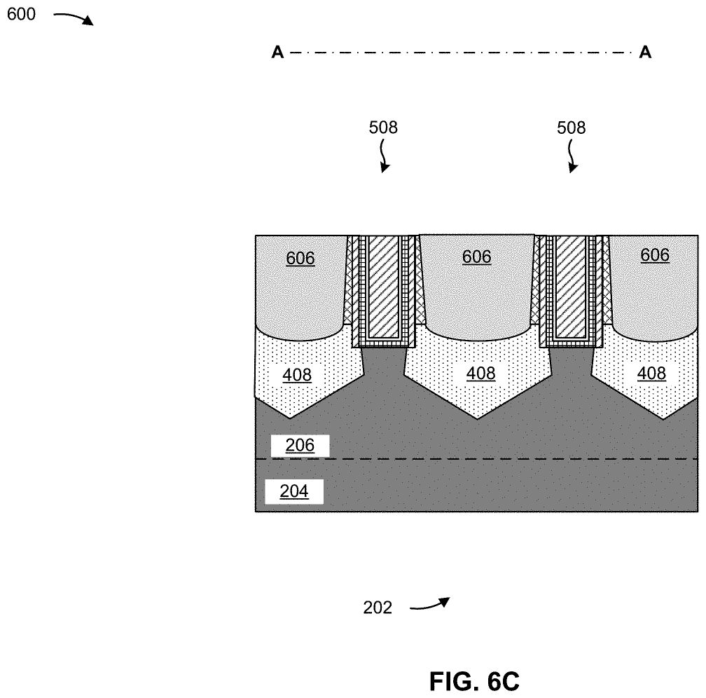

FIGS. 6A-6C are diagrams of an example implementation 600 described herein. The example implementation 600 includes an example of forming conductive structures (e.g., metal gate contacts or MDs) in the device region 202 of the semiconductor device 200. FIGS. 6A-6C are illustrated from the perspective of the cross-sectional plane A-A in FIG. 2 for the device region 202.

As shown in FIG. 6A, openings (or recesses) 602 are formed through one or more dielectric layers and to the source/drain regions 408. In particular, the CESL 502 and the ILD layer 504 between the gate structures 508 in the device region 202 are etched to form the openings 602 between the gate structures 508 and to the source/drain regions 408. In some implementations, the openings 602 are formed in a portion of the source/drain regions 408 such that recesses extend into a portion of the source/drain regions 408. An opening 602 includes a bottom surface 602a corresponding to a top surface of an associated source/drain region 408, and a plurality of sidewalls 602b corresponding to sides of the CESL 502 and/or the ILD layer 504.

In some implementations, a pattern in a photoresist layer is used to form the openings 602. In these implementations, the deposition tool 102 forms the photoresist layer on the ILD layer 504, and on the gate structures 508. The exposure tool 104 exposes the photoresist layer to a radiation source to pattern the photoresist layer. The developer tool 106 develops and removes portions of the photoresist layer to expose the pattern. The etch tool 108 etches into the ILD layer 504 to form the openings 602. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the openings 602 based on a pattern.

As shown in FIG. 6B, a pre-clean operation is performed to clean the surfaces in the openings 602. In particular, the semiconductor device 200 may be positioned in a first processing chamber of the deposition tool 102 (e.g., a pre-clean processing chamber), the first processing chamber may be pumped down to an at least partial vacuum (e.g., pressurized to a pressure that is included in a range of approximately 5 Torr to approximately 10 Torr, or to another pressure), and the bottom surfaces 602a and the sidewalls 602b in the openings 602 are cleaned using a plasma-based and/or a chemical-based pre-clean agent 604. The pre-clean operation is performed to clean (e.g., remove) oxides and other contaminants or byproducts from the top surfaces source/drain regions 408 that may have formed after the formation of the openings 602.

As shown in FIG. 6C, conductive structures 606 are formed in the device region 202. In particular, conductive structures 606 are formed in the openings 602 between the gate structures 508 and over the source/drain regions 408 in the openings 602. The deposition tool 102 and/or the plating tool 112 deposits the conductive structures 606 by a CVD technique, a PVD technique, an ALD technique, an electroplating technique, another deposition technique described above in connection with FIG. 1A, and/or a deposition technique other than as described above in connection with FIG. 1A. In some implementations, one or more additional layers are formed in the openings 602 prior to formation of the conductive structures 606. As an example, a metal silicide layer (e.g., titanium silicide (TiSiₓ) or another metal silicide layer) may be formed on the top surfaces of the source/drain regions 408 prior to formation of the conductive structures 606. As another example, one or more barrier layers may be formed on the bottom surfaces 602a and/or on the sidewalls 602b in the openings 602 prior to formation of the conductive structures 606. As another example, one or more adhesion layers may be formed on the bottom surfaces 602a and/or on the sidewalls 602b in the openings 602 prior to formation of the conductive structures 606.

As indicated above, FIGS. 6A-6C are provided as an example. Other examples may differ from what is described with regard to FIGS. 6A-6C.

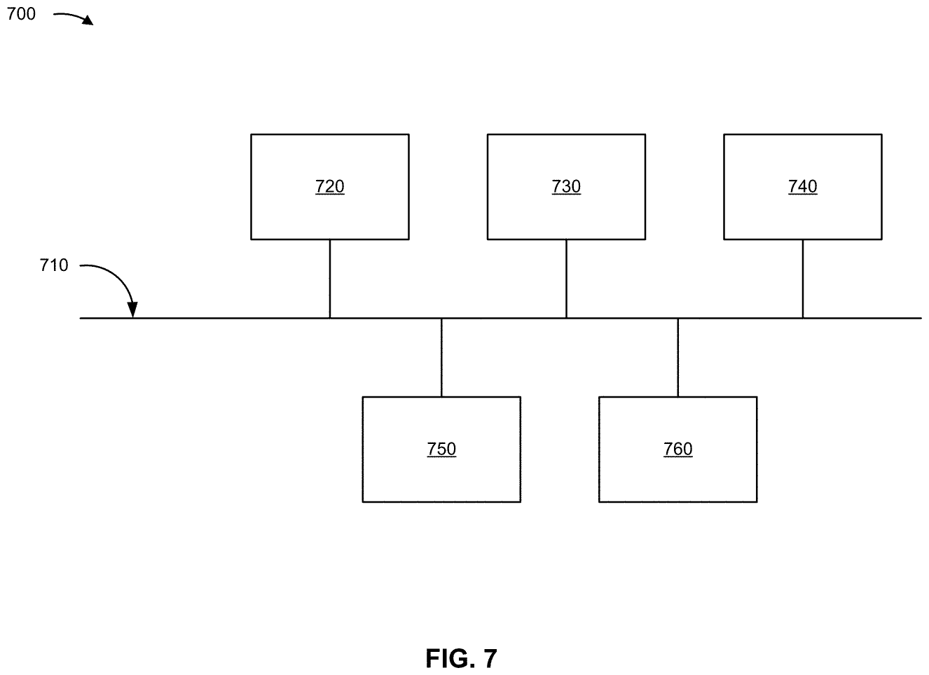

FIG. 7 is a diagram of example components of a device 700. In some implementations, one or more of the semiconductor processing tools 102-112 and/or the wafer/die transport tool 114 include one or more devices 700 and/or one or more components of device 700. As shown in FIG. 7, device 700 may include a bus 710, a processor 720, a memory 730, an input component 740, an output component 750, and a communication component 760.

Bus 710 includes one or more components that enable wired and/or wireless communication among the components of device 700. Bus 710 may couple together two or more components of FIG. 7, such as via operative coupling, communicative coupling, electronic coupling, and/or electric coupling. Processor 720 includes a central processing unit, a graphics processing unit, a microprocessor, a controller, a microcontroller, a digital signal processor, a field-programmable gate array, an application-specific integrated circuit, and/or another type of processing component. Processor 720 is implemented in hardware, firmware, or a combination of hardware and software. In some implementations, processor 720 includes one or more processors capable of being programmed to perform one or more operations or processes described elsewhere herein.

Memory 730 includes volatile and/or nonvolatile memory. For example, memory 730 may include random access memory (RAM), read only memory (ROM), a hard disk drive, and/or another type of memory (e.g., a flash memory, a magnetic memory, and/or an optical memory). Memory 730 may include internal memory (e.g., RAM, ROM, or a hard disk drive) and/or removable memory (e.g., removable via a universal serial bus connection). Memory 730 may be a non-transitory computer-readable medium. Memory 730 stores information, instructions, and/or software (e.g., one or more software applications) related to the operation of device 700. In some implementations, memory 730 includes one or more memories that are coupled to one or more processors (e.g., processor 720), such as via bus 710.

Input component 740 enables device 700 to receive input, such as user input and/or sensed input. For example, input component 740 may include a touch screen, a keyboard, a keypad, a mouse, a button, a microphone, a switch, a sensor, a global positioning system sensor, an accelerometer, a gyroscope, and/or an actuator. Output component 750 enables device 700 to provide output, such as via a display, a speaker, and/or a light-emitting diode. Communication component 760 enables device 700 to communicate with other devices via a wired connection and/or a wireless connection. For example, communication component 760 may include a receiver, a transmitter, a transceiver, a modem, a network interface card, and/or an antenna.

Device 700 may perform one or more operations or processes described herein. For example, a non-transitory computer-readable medium (e.g., memory 730) may store a set of instructions (e.g., one or more instructions or code) for execution by processor 720. Processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry is used instead of or in combination with the instructions to perform one or more operations or processes described herein. Additionally, or alternatively, processor 720 may be configured to perform one or more operations or processes described herein. Thus, implementations described herein are not limited to any specific combination of hardware circuitry and software.

The number and arrangement of components shown in FIG. 7 are provided as an example. Device 700 may include additional components, fewer components, different components, or differently arranged components than those shown in FIG. 7. Additionally, or alternatively, a set of components (e.g., one or more components) of device 700 may perform one or more functions described as being performed by another set of components of device 700.

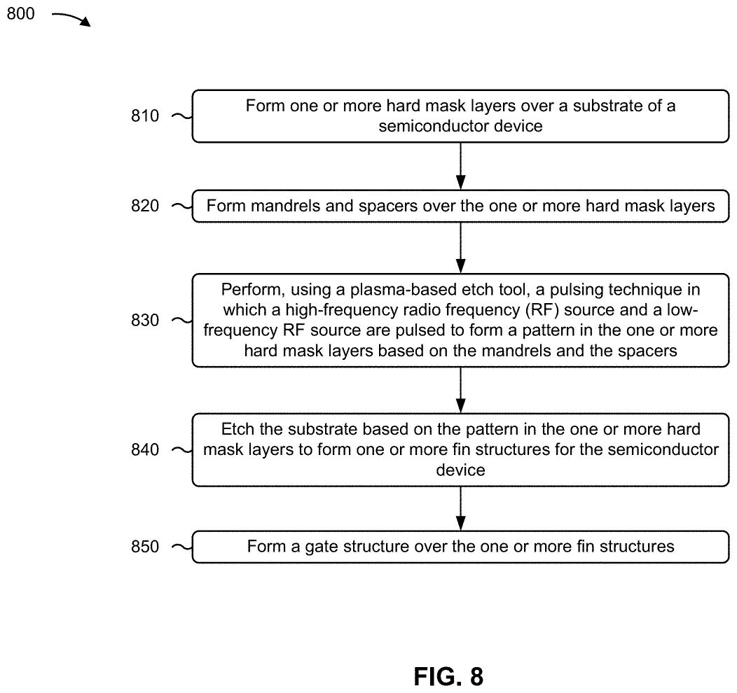

FIG. 8 is a flowchart of an example process 800 associated with forming a semiconductor device. In some implementations, one or more process blocks of FIG. 8 are performed by one or more semiconductor processing tools (e.g., one or more of the semiconductor processing tools 102-112). Additionally, or alternatively, one or more process blocks of FIG. 8 may be performed by one or more components of device 700, such as processor 720, memory 730, input component 740, output component 750, and/or communication component 760.

As shown in FIG. 8, process 800 may include forming one or more hard mask layers over a substrate of a semiconductor device (block 810). For example, one or more of the semiconductor processing tools 102-112 may form one or more hard mask layers (e.g., a first hard mask layer 304, a second hard mask layer 306) over a substrate 204 of a semiconductor device 200, as described above.

As further shown in FIG. 8, process 800 may include forming mandrels and spacers over the one or more hard mask layers (block 820). For example, one or more of the semiconductor processing tools 102-112 may form mandrels 308 and spacers 312 over the one or more hard mask layers, as described above.

As further shown in FIG. 8, process 800 may include performing, using a plasma-based etch tool, a pulsing technique in which a high-frequency RF source and a low-frequency RF source are pulsed to form a pattern in the one or more hard mask layers based on the mandrels and the spacers (block 830). For example, one or more of the etch tool 108 (which may include a plasma-based etch tool) may perform a pulsing technique in which a high-frequency RF source 122 and a low-frequency RF source 124 are pulsed to form a pattern (e.g., the first pattern 342, the second pattern 346) in the one or more hard mask layers based on the mandrels 308 and the spacers 312, as described above.

As further shown in FIG. 8, process 800 may include etching the substrate based on the pattern in the one or more hard mask layers to form one or more fin structures for the semiconductor device (block 840). For example, one or more of the semiconductor processing tools 102-112 may etch the substrate 204 based on the pattern in the one or more hard mask layers to form one or more fin structures 206 for the semiconductor device 200, as described above.

As further shown in FIG. 8, process 800 may include forming a gate structure over the one or more fin structures (block 850). For example, the one or more of the semiconductor processing tools 102-112 may form a gate structure 508 over the one or more fin structures 206, as described above.

Process 800 may include additional implementations, such as any single implementation or any combination of implementations described below and/or in connection with one or more other processes described elsewhere herein.

In a first implementation, the high-frequency RF source 122 and the low-frequency RF source 124 are pulsed such that first on durations (e.g., on duration 318a, on duration 318b) for the high-frequency RF source 122 and second on durations (e.g., on duration 322a, on duration 322b) for the low-frequency RF source 124 are non-overlapping. In a second implementation, alone or in combination with the first implementation, a starting time of an on duration (e.g., on duration 322a) of the second on durations occurs after an offset time duration 328 from a starting time of an on duration (e.g., on duration 318a) of the first on durations. In a third implementation, alone or in combination with one or more of the first and second implementations, the offset time duration comprises approximately 30% to approximately 80% of an on-and-off duration 316 in which the on duration 322a of the first on durations occurs.

In a fourth implementation, alone or in combination with one or more of the first through third implementations, a duty cycle of the second on durations is greater relative to a duty cycle of the first on durations. In a fifth implementation, alone or in combination with one or more of the first through fourth implementations, the pulsing technique, in which the high-frequency RF source 122 and the low-frequency RF source 124 are pulsed, reduces a magnitude of a reduction in a height (H1) of the one or more hard mask layers. In a sixth implementation, alone or in combination with one or more of the first through fifth implementations, the pulsing technique, in which the high-frequency RF source 122 and the low-frequency RF source 124 are pulsed, promotes reduced LER for the one or more fin structures 206.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

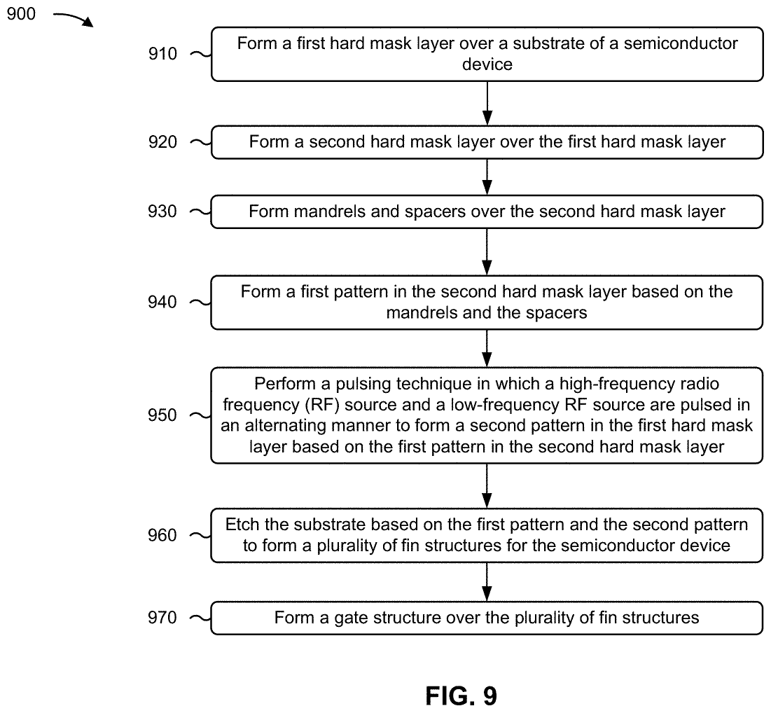

FIG. 9 is a flowchart of an example process 900 associated with forming a semiconductor device. In some implementations, one or more process blocks of FIG. 9 are performed by one or more semiconductor processing tools (e.g., one or more of the semiconductor processing tools 102-112). Additionally, or alternatively, one or more process blocks of FIG. 9 may be performed by one or more components of device 700, such as processor 720, memory 730, input component 740, output component 750, and/or communication component 760.

As shown in FIG. 9, process 900 may include forming a first hard mask layer over a substrate of a semiconductor device (block 910). For example, one or more of the semiconductor processing tools 102-112 may form a first hard mask layer 304 over a substrate 204 of a semiconductor device 200, as described above.

As further shown in FIG. 9, process 900 may include forming a second hard mask layer (306) over the first hard mask layer (block 920). For example, one or more of the semiconductor processing tools 102-112 may form a second hard mask layer 306 over the first hard mask layer 304, as described above.

As further shown in FIG. 9, process 900 may include forming mandrels and spacers over the second hard mask layer (block 930). For example, the one or more of the semiconductor processing tools 102-112 may form mandrels 308 and spacers 312 over the second hard mask layer 306, as described above.

As further shown in FIG. 9, process 900 may include forming a first pattern in the second hard mask layer based on the mandrels and the spacers (block 940). For example, one or more of the semiconductor processing tools 102-112 may form a first pattern 342 in the second hard mask layer 306 based on the mandrels 308 and the spacers 312, as described above.

As further shown in FIG. 9, process 900 may include performing a pulsing technique in which a high-frequency RF source and a low-frequency RF source are pulsed in an alternating manner to form a second pattern in the first hard mask layer based on the first pattern in the second hard mask layer (block 950). For example, one or more of the semiconductor processing tools 102-112 may perform a pulsing technique in which a high-frequency RF source 122 and a low-frequency RF source 124 are pulsed in an alternating manner to form a second pattern 346 in the first hard mask layer 304 based on the first pattern 342 in the second hard mask layer 306, as described above.

As further shown in FIG. 9, process 900 may include etching the substrate based on the first pattern and the second pattern to form a plurality of fin structures for the semiconductor device (block 960). For example, one or more of the semiconductor processing tools 102-112 may etch the substrate 204 based on the first pattern 342 and the second pattern 346 to form a plurality of fin structures 206 for the semiconductor device 200, as described above.

As further shown in FIG. 9, process 900 may include forming a gate structure over the plurality of fin structures (block 970). For example, one or more of the semiconductor processing tools 102-112 may form a gate structure 508 over the plurality of fin structures 206, as described above.

Process 900 may include additional implementations, such as any single implementation or any combination of implementations described below and/or in connection with one or more other processes described elsewhere herein.

In a first implementation, the high-frequency RF source 122 and the low-frequency RF source 124 are pulsed such that on durations (e.g., on duration 318a, on duration 318b) for the high-frequency RF source 122 occur during off durations (e.g., off durations 324) for the low-frequency RF source 124, and the high-frequency RF source 122 and the low-frequency RF source 124 are pulsed such that on durations (e.g., on duration 322a, on duration 322b) for the low-frequency RF source 124 occur during off durations (e.g., off durations 320) for the high-frequency RF source 122. In a second implementation, alone or in combination with the first implementation, the first hard mask layer 304 includes a silicon nitride (SiₓN_{y}) material and the second hard mask layer 306 includes a silicon oxide (SiOₓ) material. In a third implementation, alone or in combination with one or more of the first and second implementations, the pulsing technique, in which the high-frequency RF source 122 and the low-frequency RF source 124 are pulsed in the alternating manner, promotes increased etch depth between adjacent fin structures 206 of the plurality of fin structures 206.

In a fourth implementation, alone or in combination with one or more of the first through third implementations, the high-frequency RF source 122 is pulsed at a first frequency, the low-frequency RF source 124 is pulsed at a second frequency, and the first frequency and the second frequency are each included in a range of approximately 50 hertz to approximately 1000 hertz. In a fifth implementation, alone or in combination with one or more of the first through fourth implementations, a height (H1) of the second hard mask layer 306 after the second pattern 346 is formed in the first hard mask layer 304 is in a range of approximately 40 nm to approximately 50 nm. In a sixth implementation, alone or in combination with one or more of the first through fifth implementations, the high-frequency RF source 122 and the low-frequency RF source 124 are pulsed in the alternating manner to control a ratio of ions to radicals while etching the first hard mask layer 304 to form the second pattern 346.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

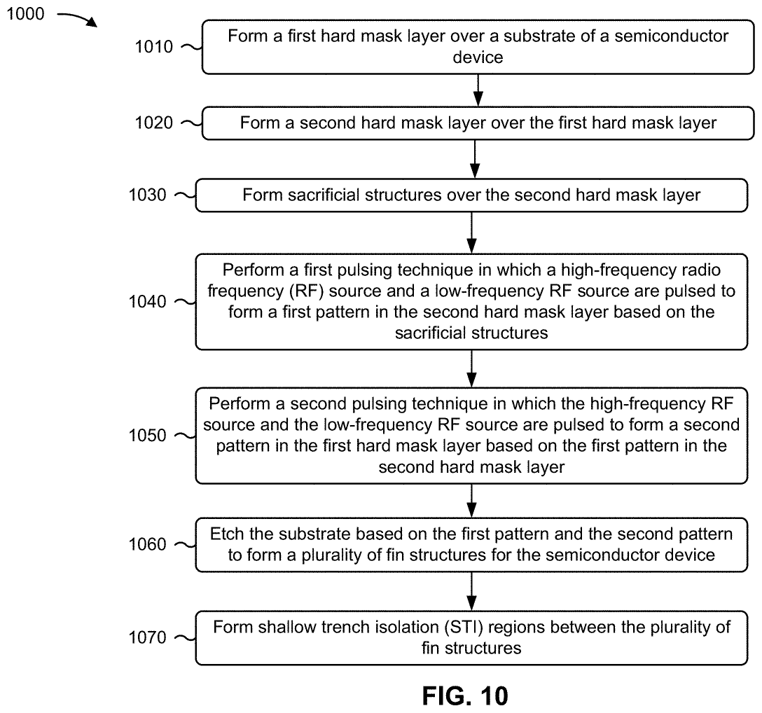

FIG. 10 is a flowchart of an example process 1000 associated with forming a semiconductor device. In some implementations, one or more process blocks of FIG. 10 are performed by one or more semiconductor processing tools (e.g., one or more of the semiconductor processing tools 102-112). Additionally, or alternatively, one or more process blocks of FIG. 10 may be performed by one or more components of device 700, such as processor 720, memory 730, input component 740, output component 750, and/or communication component 760.

As shown in FIG. 10, process 1000 may include forming a first hard mask layer over a substrate of a semiconductor device (block 1010). For example, one or more of the semiconductor processing tools 102-112 may form a first hard mask layer 304 over a substrate 204 of a semiconductor device 200, as described above.

As further shown in FIG. 10, process 1000 may include forming a second hard mask layer over the first hard mask layer (block 1020). For example, one or more of the semiconductor processing tools 102-112 may form a second hard mask layer 306 over the first hard mask layer 304, as described above.

As further shown in FIG. 10, process 1000 may include forming sacrificial structures over the second hard mask layer (block 1030). For example, one or more of the semiconductor processing tools 102-112 may form sacrificial structures (e.g., mandrels 308, spacers 312) over the second hard mask layer 306, as described above.

As further shown in FIG. 10, process 1000 may include performing a first pulsing technique in which a high-frequency RF source and a low-frequency RF source are pulsed to form a first pattern in the second hard mask layer based on the sacrificial structures (block 1040). For example, one or more of the semiconductor processing tools 102-112 may perform a first pulsing technique in which a high-frequency RF source 122 and a low-frequency RF source 124 are pulsed to form a first pattern 342 in the second hard mask layer 306 based on the sacrificial structures, as described above.

As further shown in FIG. 10, process 1000 may include performing a second pulsing technique in which the high-frequency RF source and the low-frequency RF source are pulsed to form a second pattern in the first hard mask layer based on the first pattern in the second hard mask layer (block 1050). For example, one or more of the semiconductor processing tools 102-112 may perform a second pulsing technique in which the high-frequency RF source 122 and the low-frequency RF source 124 are pulsed to form a second pattern 346 in the first hard mask layer 304 based on the first pattern 342 in the second hard mask layer 306, as described above.

As further shown in FIG. 10, process 1000 may include etching the substrate based on the first pattern and the second pattern to form a plurality of fin structures for the semiconductor device (block 1060). For example, one or more of the semiconductor processing tools 102-112 may etch the substrate 204 based on the first pattern 342 and the second pattern 346 to form a plurality of fin structures 206 for the semiconductor device 200, as described above.

As further shown in FIG. 10, process 1000 may include forming STI regions between the plurality of fin structures (block 1070). For example, one or more of the semiconductor processing tools 102-112 may form STI regions 208 between the plurality of fin structures 206, as described above.

Process 1000 may include additional implementations, such as any single implementation or any combination of implementations described below and/or in connection with one or more other processes described elsewhere herein.

In a first implementation, performing the second pulsing technique comprises performing the second pulsing technique in a first etch operation to etch a first portion of the first hard mask layer, and performing the second pulsing technique in a second etch operation after the first etch operation to etch a second portion of the first hard mask layer. In a second implementation, alone or in combination with the first implementation, the high-frequency RF source 122 and the low-frequency RF source 124 are pulsed such that a starting time for an on-and-off duration (e.g., an on-and-off duration 324) for the low-frequency RF source 124 occurs after an offset time duration (e.g., an offset time duration 328) from a starting time of an on-and-off duration (e.g., an on-and-off duration 316) for the high-frequency RF source 122.

In a third implementation, alone or in combination with one or more of the first and second implementations, the offset time duration includes approximately 30% to approximately 80% of the on-and-off duration 316 for the low-frequency RF source 124. In a fourth implementation, alone or in combination with one or more of the first through third implementations, performing the first pulsing technique and performing the second pulsing technique reduces a likelihood of under etch defect formation for the plurality of fin structures 206. In a fifth implementation, alone or in combination with one or more of the first through fourth implementations, the high-frequency RF source 122 is pulsed at a first frequency, the low-frequency RF source 124 is pulsed at a second frequency, and the first frequency and the second frequency are each included in a range of approximately 50 hertz to approximately 1000 hertz.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, the multiple-patterning techniques described herein enable forming fin structures of a semiconductor device in a manner that enables decreased fin-to-fin spacing of the fin structures while providing precise control over etching depth of the fin structures. In some implementations, an etch operation is performed to form a pattern in one or more mask layers that is used to etch a substrate to form the fin structures. The etch operation includes an advanced pulsing technique, in which a high-frequency RF source and a low-frequency RF source are pulsed. Pulsing the high-frequency RF source and the low-frequency RF source in the etch operation reduces consumption of a thickness of the one or more mask layers which increases the aspect ratio of the pattern. This enables deeper etching of the substrate when forming the fin structures, which reduces the likelihood of under etching.

As described in greater detail above, some implementations described herein provide a method. The method includes forming one or more hard mask layers over a substrate of a semiconductor device. The method includes forming mandrels and spacers over the one or more hard mask layers. The method includes performing, using a plasma-based etch tool, a pulsing technique in which a high-frequency RF source and a low-frequency RF source are pulsed to form a pattern in the one or more hard mask layers based on the mandrels and the spacers. The method includes etching the substrate based on the pattern in the one or more hard mask layers to form one or more fin structures for the semiconductor device. The method includes forming a gate structure over the one or more fin structures.

As described in greater detail above, some implementations described herein provide a method. The method includes forming a first hard mask layer over a substrate of a semiconductor device. The method includes forming a second hard mask layer over the first hard mask layer. The method includes forming mandrels and spacers over the second hard mask layer. The method includes forming a first pattern in the second hard mask layer based on the mandrels and the spacers. The method includes performing a pulsing technique in which a high-frequency RF source and a low-frequency RF source are pulsed in an alternating manner to form a second pattern in the first hard mask layer based on the first pattern in the second hard mask layer. The method includes etching the substrate based on the first pattern and the second pattern to form a plurality of fin structures for the semiconductor device. The method includes forming a gate structure over the plurality of fin structures.

As described in greater detail above, some implementations described herein provide a method. The method includes forming a first hard mask layer over a substrate of a semiconductor device. The method includes forming a second hard mask layer over the first hard mask layer. The method includes forming sacrificial structures over the second hard mask layer. The method includes performing a first pulsing technique in which a high-frequency RF source and a low-frequency RF source are pulsed to form a first pattern in the second hard mask layer based on the sacrificial structures. The method includes performing a second pulsing technique in which the high-frequency RF source and the low-frequency RF source are pulsed to form a second pattern in the first hard mask layer based on the first pattern in the second hard mask layer. The method includes etching the substrate based on the first pattern and the second pattern to form a plurality of fin structures for the semiconductor device. The method includes forming STI regions between the plurality of fin structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more hard mask layers over a substrate of a semiconductor device;
forming mandrels and spacers over the one or more hard mask layers;
performing, using a plasma-based etch tool, a pulsing technique in which a high-frequency radio frequency (RF) source and a low-frequency RF source are pulsed to form a pattern in the one or more hard mask layers based on the mandrels and the spacers;
etching the substrate based on the pattern in the one or more hard mask layers to form one or more fin structures for the semiconductor device; and
forming a gate structure over the one or more fin structures.

2. The method of claim 1, wherein the high-frequency RF source and the low-frequency RF source are pulsed such that first on durations for the high-frequency RF source and second on durations for the low-frequency RF source are non-overlapping.

3. The method of claim 2, wherein a starting time of an on duration of the second on durations occurs after an offset time duration from a starting time of an on duration of the first on durations.

4. The method of claim 3, wherein the offset time duration comprises approximately 30% to approximately 80% of an on-and-off duration (316) in which the on duration of the first on durations occurs.

5. The method of claim 2, wherein a duty cycle of the second on durations is greater relative to a duty cycle of the first on durations.

6. The method of claim 1, wherein the pulsing technique, in which the high-frequency RF source and the low-frequency RF source are pulsed, reduces a magnitude of a reduction in a height (H1) of the one or more hard mask layers.

7. The method of claim 1, wherein the pulsing technique, in which the high-frequency RF source and the low-frequency RF source are pulsed, promotes reduced line edge roughness (LER) for the one or more fin structures.

8. A method, comprising:
forming a first hard mask layer over a substrate of a semiconductor device;
forming a second hard mask layer over the first hard mask layer;
forming mandrels and spacers over the second hard mask layer;
forming a first pattern in the second hard mask layer based on the mandrels and the spacers;
performing a pulsing technique in which a high-frequency radio frequency (RF) source and a low-frequency RF source are pulsed in an alternating manner to form a second pattern in the first hard mask layer based on the first pattern in the second hard mask layer;
etching the substrate based on the first pattern and the second pattern to form a plurality of fin structures for the semiconductor device; and
forming a gate structure over the plurality of fin structures.

9. The method of claim 8, wherein the high-frequency RF source and the low-frequency RF source are pulsed such that on durations for the high-frequency RF source occur during off durations for the low-frequency RF source; and
wherein the high-frequency RF source and the low-frequency RF source are pulsed such that on durations for the low-frequency RF source occur during off durations for the high-frequency RF source.

10. The method of claim 8, wherein the first hard mask layer comprises a silicon nitride (SiₓN_{y}) material; and
wherein the second hard mask layer comprises a silicon oxide (SiOₓ) material.

11. The method of claim 8, wherein the pulsing technique, in which the high-frequency RF source and the low-frequency RF source are pulsed in the alternating manner, promotes increased etch depth between adjacent fin structures of the plurality of fin structures.

12. The method of claim 8, wherein the high-frequency RF source is pulsed at a first frequency;
wherein the low-frequency RF source is pulsed at a second frequency; and
wherein the first frequency and the second frequency are each included in a range of approximately 50 hertz to approximately 1000 hertz.

13. The method of claim 8, wherein a height (H1) of the second hard mask layer after the second pattern is formed in the first hard mask layer is in a range of approximately 40 nanometers to approximately 50 nanometers.

14. The method of claim 8, wherein the high-frequency RF source and the low-frequency RF source are pulsed in the alternating manner to control a ratio of ions to radicals while etching the first hard mask layer to form the second pattern.

15. A method, comprising:
forming a first hard mask layer over a substrate of a semiconductor device;
forming a second hard mask layer over the first hard mask layer;
forming sacrificial structures over the second hard mask layer;
performing a first pulsing technique in which a high-frequency radio frequency (RF) source and a low-frequency RF source are pulsed to form a first pattern in the second hard mask layer based on the sacrificial structures;
performing a second pulsing technique in which the high-frequency RF source and the low-frequency RF source are pulsed to form a second pattern in the first hard mask layer based on the first pattern in the second hard mask layer;
etching the substrate based on the first pattern and the second pattern to form a plurality of fin structures for the semiconductor device; and
forming shallow trench isolation (STI) regions between the plurality of fin structures.

16. The method of claim 15, wherein performing the second pulsing technique comprises:
performing the second pulsing technique in a first etch operation to etch a first portion of the first hard mask layer; and
performing the second pulsing technique in a second etch operation after the first etch operation to etch a second portion of the first hard mask layer.

17. The method of claim 15, wherein the high-frequency RF source and the low-frequency RF source are pulsed such that a starting time for an on-and-off duration for the low-frequency RF source occurs after an offset time duration from a starting time of an on-and-off duration for the high-frequency RF source.

18. The method of claim 17, wherein the offset time duration comprises approximately 30% to approximately 80% of the on-and-off duration for the low-frequency RF source.

19. The method of claim 15, wherein performing the first pulsing technique and performing the second pulsing technique reduces a likelihood of under etch defect formation for the plurality of fin structures.

20. The method of claim 15, wherein the high-frequency RF source is pulsed at a first frequency;
wherein the low-frequency RF source is pulsed at a second frequency; and
wherein the first frequency and the second frequency are each included in a range of approximately 50 hertz to approximately 1000 hertz.
